(19) United States
(12) Patent Application Publication
(10) Pub. No.: US 2025/0119163 A1
(43) Pub. Date: Apr. 10, 2025

(54) ENCODING METHOD AND APPARATUS, DECODING METHOD AND APPARATUS, AND DEVICE

(71) Applicant: HUAWEI TECHNOLOGIES CO., LTD., Shenzhen (CN)

(72) Inventors: Huazi ZHANG, Hangzhou (CN); Jiajie TONG, Hangzhou (CN); Xianbin WANG, Hangzhou (CN); Shengchen DAI, Hangzhou (CN); Rong LI, Boulogne Billancourt (FR); Jun WANG, Hangzhou (CN)

(21) Appl. No.: 18/903,370

(22) Filed: Oct. 1, 2024

Related U.S. Application Data
(63) Continuation of application No. 17/969,736, filed on Oct. 20, 2022, now Pat. No. 12,136,932.
Application No. 17/969,736 is a continuation of application No. PCT/CN2021/086960, filed on Apr. 13, 2021.

(30) Foreign Application Priority Data
Apr. 22, 2020 (CN) 202010323605.X

(51) Int. Cl. H03M 13/13; H04L 1/00

(52) U.S. Cl. CPC H03M 13/118; H03M 13/1125; H03M 13/1137

(57) ABSTRACT

An encoding method and apparatus, a decoding method and apparatus, and a device are provided. The encoding method includes: obtaining K to-be-encoded bits (S301), where K is a positive integer; determining a first generator matrix, where the first generator matrix includes at least two sub-blocks distributed based on a preset position relationship, and the sub-block includes a plurality of first generator matrix cores (S302); generating a second generator matrix based on the first generator matrix, where the second generator matrix includes T sub-blocks, and a position relationship between two adjacent sub-blocks of the T sub-blocks is determined based on the preset position relationship (S303), where T is a positive integer; and polar encoding the K to-be-encoded bits based on the second generator matrix (S304), to obtain encoded bits. This can reduce encoding/decoding complexity.

### CROSS-REFERENCE TO RELATED APPLICATIONS

This application is a continuation of U.S. patent application Ser. No. 17/969,736, filed on Oct. 20, 2022, which is a continuation of International Application No. PCT/CN2021/086960, filed on Apr. 13, 2021, which claims priority to Chinese Patent Application No. 202010323605.X, filed on Apr. 22, 2020. The disclosures of the aforementioned applications are hereby incorporated by reference in their entireties.

### TECHNICAL FIELD

This application relates to the field of communication technologies, and in particular, to an encoding method and apparatus, a decoding method and apparatus, and a device.

### BACKGROUND

In the field of communication technologies, a communication device (for example, a terminal device or a base station) may perform channel encoding and decoding by using a polar code (Polar code).

When decoding is performed by using a polar code, encoding/decoding (encoding and/or decoding) complexity is usually related to a code length. A larger code length indicates higher encoding/decoding complexity. When the code length is very large (for example, the code length is greater than 16384), complexity of performing encoding/decoding by using the polar code is very high, resulting in poor encoding/decoding performance.

### SUMMARY

Embodiments of this application provide an encoding method and apparatus, a decoding method and apparatus, and a device, to reduce encoding/decoding complexity.

According to a first aspect, an embodiment of this application provides an encoding method. The method includes: obtaining K to-be-encoded bits, where K is a positive integer; determining a first generator matrix, where the first generator matrix includes at least two sub-blocks distributed based on a preset position relationship, and the sub-block includes a plurality of first generator matrix cores; generating a second generator matrix based on the first generator matrix, where the second generator matrix includes T sub-blocks, and a position relationship between two adjacent sub-blocks of the T sub-blocks is determined based on the preset position relationship, where T is a positive integer; and polar encoding the K to-be-encoded bits based on the second generator matrix, to obtain encoded bits.

In the foregoing process, when the K to-be-encoded bits need to be encoded, the first generator matrix is first determined, then the second generator matrix is generated based on the first generator matrix, and the K to-be-encoded bits are polar encoded based on the second generator matrix. The first generator matrix includes the at least two sub-blocks distributed based on the preset position relationship, each sub-block includes a plurality of first generator matrix cores, the second generator matrix includes the T sub-blocks, and the position relationship between two adjacent sub-blocks of the T sub-blocks is determined based on the preset position relationship. Therefore, it may be learned that the second generator matrix includes a plurality of sub-blocks arranged according to the foregoing preset position relationship, and each sub-block includes a plurality of first generator matrix cores. Therefore, polar encoding the K to-be-encoded bits based on the second generator matrix is equivalent to: polar encoding a plurality of short codes, and coupling the plurality of short codes to obtain an encoding result. This can reduce encoding complexity.

In a possible implementation, the position relationship between two adjacent sub-blocks of the T sub-blocks is the same as the preset position relationship.

In the foregoing process, the position relationship between two adjacent sub-blocks of the T sub-blocks in the second generator matrix is the same as the preset position relationship, so that short codes have a same coupling manner, and encoding complexity is low.

In a possible implementation, an overlapping portion exists in the at least two sub-blocks.

In the foregoing process, because an overlapping portion exists between two sub-blocks, different short codes can be coupled.

In a possible implementation, first generator matrix cores are included on a first diagonal of the sub-block.

In a possible implementation, the plurality of first generator matrix cores in the sub-block are distributed in a lower triangular form.

In a possible implementation, distribution of the first generator matrix cores in the sub-block is the same as distribution of first elements in a second generator matrix core, a quantity of elements included in the second generator matrix core is the same as a quantity of sub-matrices included in the sub-block, and a sub-matrix included in the sub-block is the first generator matrix core or a zero matrix.

In the foregoing process, because distribution of the first generator matrix cores in the sub-block is the same as distribution of the first elements in the second generator matrix core, a coupling manner of short codes is similar to that in an existing encoding scheme, and therefore encoding complexity is low.

In a possible implementation, the first generator matrix includes two sub-blocks.

In the foregoing process, the second generator matrix includes a small quantity of sub-blocks, and the second generator matrix is easy to construct.

In a possible implementation, the quantity of sub-matrices included in the sub-block is 2*2, and the sub-matrix included in the sub-block is the first generator matrix core or the zero matrix.

In a possible implementation, the first generator matrix includes a first sub-block and a second sub-block, and a first sub-matrix in the first sub-block overlaps a second sub-matrix in the second sub-block; and coordinates of the first sub-matrix in the first sub-block are (2, 2), and coordinates of the second sub-matrix in the second sub-block are (1, 1).

In the foregoing process, the second generator matrix is symmetrical in a direction of a secondary diagonal of the second generator matrix, and therefore encoding complexity is low, and decoding complexity is also low.

In a possible implementation, the quantity of sub-matrices included in the sub-block is 4*4, and the sub-matrix included in the sub-block is the first generator matrix core or the zero matrix.

In a possible implementation, the first generator matrix includes a first sub-block and a second sub-block, and four first sub-matrices in the first sub-block overlap four second sub-matrices in the second sub-block. Coordinates of the four first sub-matrices in the first sub-block are (3, 3), (3, 4), (4, 3), and (4, 4); and coordinates of the four second sub-matrices in the second sub-block are (1, 1), (1, 2), (2, 1), and (2, 2).

In the foregoing process, the second generator matrix is symmetrical in a direction of a secondary diagonal of the second generator matrix, and therefore encoding complexity is low, and decoding complexity is also low.

In a possible implementation, the K to-be-encoded bits are information bits. The polar encoding the K to-be-encoded bits based on the second generator matrix, to obtain encoded bits includes: determining K sub-channels with highest reliability in a plurality of sub-channels corresponding to the K to-be-encoded bits; determining positions of the K to-be-encoded bits based on the K sub-channels with the highest reliability; determining a to-be-encoded sequence based on the positions of the K to-be-encoded bits, where the to-be-encoded sequence includes the K to-be-encoded bits and frozen bits; and polar encoding the to-be-encoded sequence based on the second generator matrix, to obtain the encoded bits.

In the foregoing process, a sub-channel with highest reliability is selected to transmit information bits, and therefore encoding performance is high.

In a possible implementation, the plurality of sub-channels include P groups of sub-channels, where P is a positive integer. The determining K sub-channels with highest reliability in a plurality of sub-channels corresponding to the K to-be-encoded bits includes: determining Xᵢ first sub-channels from an i^{th} group of sub-channels based on reliability of the i^{th} group of sub-channels, where the Xᵢ first sub-channels are Xᵢ sub-channels with highest reliability in the i^{th} group of sub-channels, i is an integer, 1≤i≤P, Xᵢ is a positive integer, and Σᵢ₌₁^{i=P} Xᵢ=K. The K sub-channels with the highest reliability include the first sub-channels.

According to a second aspect, an embodiment of this application provides a decoding method. The method includes: receiving polar encoded bit information; and polar decoding the bit information based on a second generator matrix, to obtain polar decoded bits. The second generator matrix is generated based on a first generator matrix, the first generator matrix includes at least two sub-blocks distributed based on a preset position relationship, the sub-block includes a plurality of first generator matrix cores, the second generator matrix includes T sub-blocks, and a position relationship between two adjacent sub-blocks of the T sub-blocks is determined based on the preset position relationship, where T is a positive integer.

In the foregoing decoding process, the first generator matrix includes the at least two sub-blocks distributed based on the preset position relationship, each sub-block includes a plurality of first generator matrix cores, the second generator matrix includes the T sub-blocks, and the position relationship between two adjacent sub-blocks of the T sub-blocks is determined based on the preset position relationship. Therefore, it may be learned that the second generator matrix includes a plurality of sub-blocks arranged according to the foregoing preset position relationship, and each sub-block includes a plurality of first generator matrix cores. Therefore, polar decoding the bit information based on the second generator matrix is equivalent to: decoupling a plurality of short codes, and decoding the decoupled short codes. Because complexity of decoding the short codes, decoding complexity is low.

In a possible implementation, the position relationship between two adjacent sub-blocks of the T sub-blocks is the same as the preset position relationship.

In the foregoing process, the position relationship between two adjacent sub-blocks of the T sub-blocks in the second generator matrix is the same as the preset position relationship, so that short codes have a same coupling manner, and decoding complexity is low.

In a possible implementation, an overlapping portion exists in the at least two sub-blocks.

In the foregoing process, because an overlapping portion exists between two sub-blocks, different short codes can be coupled.

In a possible implementation, first generator matrix cores are included on a first diagonal of the sub-block.

In a possible implementation, the plurality of first generator matrix cores in the sub-block are distributed in a lower triangular form.

In a possible implementation, distribution of the first generator matrix cores in the sub-block is the same as distribution of first elements in a second generator matrix core, a quantity of elements included in the second generator matrix core is the same as a quantity of sub-matrices included in the sub-block, and a sub-matrix included in the sub-block is the first generator matrix core or a zero matrix.

In the foregoing process, because distribution of the first generator matrix cores in the sub-block is the same as distribution of the first elements in the second generator matrix core, a coupling manner of short codes is similar to that in an existing decoding scheme, and therefore decoding complexity is low.

In a possible implementation, the first generator matrix includes two sub-blocks.

In the foregoing process, the second generator matrix includes a small quantity of sub-blocks, and the second generator matrix is easy to construct.

In a possible implementation, the quantity of sub-matrices included in the sub-block is 2*2, and the sub-matrix included in the sub-block is the first generator matrix core or the zero matrix.

In a possible implementation, the first generator matrix includes a first sub-block and a second sub-block, and a first sub-matrix in the first sub-block overlaps a second sub-matrix in the second sub-block; and coordinates of the first sub-matrix in the first sub-block are (2, 2), and coordinates of the second sub-matrix in the second sub-block are (1, 1).

In the foregoing process, the second generator matrix is symmetrical in a direction of a secondary diagonal of the second generator matrix, and therefore decoding complexity is low.

In a possible implementation, the quantity of sub-matrices included in the sub-block is 4*4, and the sub-matrix included in the sub-block is the first generator matrix core or the zero matrix.

In a possible implementation, the first generator matrix includes a first sub-block and a second sub-block, and four first sub-matrices in the first sub-block overlap four second sub-matrices in the second sub-block. Coordinates of the four first sub-matrices in the first sub-block are (3, 3), (3, 4), (4, 3), and (4, 4); and coordinates of the four second sub-matrices in the second sub-block are (1, 1), (1, 2), (2, 1), and (2, 2).

In the foregoing process, the second generator matrix is symmetrical in a direction of a secondary diagonal of the second generator matrix, and therefore decoding complexity is low.

In a possible implementation, the bit information includes N′ first log-likelihood ratio LLR sequences, where N′ is a positive integer.

In a possible implementation, the N′ first LLRs include T first LLR sequences, and the first LLR sequence includes at least two first LLRs. Polar decoding includes: determining T second LLR sequences corresponding to the T first LLR sequences, where one of the first LLR sequences corresponds to one or more groups of unencoded bits, and one of the second LLR sequences corresponds to one group of unencoded bits; and performing polar decoding based on the T second LLR sequences.

In the foregoing process, the T coupled first LLR sequences are first decoupled to obtain the T decoupled second LLR sequences, and then the T decoupled second LLR sequences are decoded. Because a length of the second LLR sequence is small, complexity of decoding the second LLR sequence is low, and decoding complexity is low.

In a possible implementation, the determining T second LLR sequences corresponding to the T first LLR sequences includes: determining an i^{th} second LLR sequence based on an i^{th} first LLR sequence and at least one of first (i−1) second LLR sequences, where i is an integer between 2 and T.

In the foregoing process, when the i^{th} second LLR sequence is determined, the first LLR sequences are decoupled based on the i^{th} first LLR sequence and the at least one of the decoupled first (i−1) second LLR sequences, to obtain the i^{th} second LLR sequence.

In a possible implementation, a coupling degree of a code block is 2. The determining an i^{th} second LLR sequence based on an i^{th} first LLR sequence and at least one of first (i−1) second LLR sequences includes: determining the i^{th} second LLR sequence based on the i^{th} first LLR sequence and an (i−1)th second LLR sequence.

In a possible implementation, a 1^{st} second LLR sequence is the same as a 1^{st} first LLR sequence.

In a possible implementation, a coupling degree of a code block is 4. The determining an i^{th} second LLR sequence based on an i^{th} first LLR sequence and at least one of first (i−1) second LLR sequences includes: determining the i^{th} second LLR sequence based on the i^{th} first LLR sequence and an (i−2)th second LLR sequence, where i is an integer between 3 and T.

In a possible implementation, a 1^{st} second LLR sequence is the same as a 1^{st} first LLR sequence, and a 2^{nd} second LLR sequence is the same as a 2^{nd} first LLR sequence.

In a possible implementation, polar decoding may be performed based on the T second LLR sequences in the following manner: determining to obtain a T^{th} decoding result based on a T^{th} second LLR sequence; and determining an i^{th} decoding result based on the i^{th} second LLR sequence and at least one of an (i+1)^{th} decoding result to the T^{th} decoding result, where i is an integer between 1 and T−1.

In the foregoing process, the second LLR sequence (short code) is decoded to obtain a decoding result, and therefore decoding complexity is low.

In a possible implementation, a coupling degree of a code block is 2. The determining an i^{th} decoding result based on the i^{th} second LLR sequence and at least one of an (i+1)^{th} decoding result to the T^{th} decoding result includes: determining the i^{th} decoding result based on the (i+1)^{th} decoding result, an (i+1)^{th} first LLR sequence, and the i^{th} second LLR sequence.

According to a third aspect, an embodiment of this application provides an encoding method. The method includes: obtaining K to-be-encoded bits, where K is a positive integer; determining a first generator matrix, where the first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1; determining a second generator matrix based on an encoding length and the first generator matrix, where the second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2; and polar encoding the K to-be-encoded bits based on the second generator matrix, to obtain encoded bits.

In the foregoing process, when the K to-be-encoded bits need to be encoded, the first generator matrix is first determined, then the second generator matrix is generated based on the first generator matrix, and the K to-be-encoded bits are polar encoded based on the second generator matrix. Because the first generator matrix has self-similarity, and the second generator matrix includes a plurality of first matrix blocks, polar encoding the K to-be-encoded bits based on the second generator matrix is equivalent to: polar encoding a plurality of short codes, and coupling the plurality of short codes, to obtain an encoding result. This can reduce encoding complexity.

In a possible implementation, no overlapping element exists in the first matrix block and the second matrix block.

In a possible implementation, a size of the first generator matrix is v*v, and an element in the first generator matrix satisfies a_{i,j}=a_{i+u,j+u}, where i is an integer, j is an integer, v is a positive integer, u is an integer, 1≤i<v, 1≤j<v, 1<i+u≤v, and 1<j+u≤v.

In the foregoing process, when the first generator matrix satisfies a_{i,j}=a_{i+u,j+u}, the first generator matrix satisfies the self-similarity. Polar encoding the K to-be-encoded bits based on the second generator matrix is equivalent to: polar encoding a plurality of short codes, and coupling the plurality of short codes, to obtain an encoding result. This can reduce encoding complexity.

In a possible implementation, elements in the first generator matrix are symmetrical along a secondary diagonal of the first generator matrix.

In the foregoing process, because the elements in the first generator matrix are symmetrical along the secondary diagonal of the first generator matrix, encoding complexity is low.

In a possible implementation, T is a minimum integer that enables a first condition to be satisfied, and the first condition is that a size of the second generator matrix is greater than or equal to the encoding length.

In a possible implementation, T satisfies the following relationship: v+(T−1)*u<N′≤v+T*u, where v is the size of the first generator matrix, N′ is the encoding length, and N′ is an integer greater than 1.

In the foregoing process, an excessively large or small size of the second generator matrix may be avoided, and therefore encoding complexity is low.

According to a fourth aspect, an embodiment of this application provides a decoding method. The method may include: receiving polar encoded bit information; and polar decoding the bit information based on a second generator matrix, to obtain polar decoded bits. The second generator matrix is generated based on a first generator matrix, the first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1. The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

In the foregoing process, because the first generator matrix has self-similarity, and the second generator matrix includes a plurality first matrix blocks. Therefore, polar decoding the bit information based on the second generator matrix is equivalent to: decoupling a plurality of short codes, and decoding the decoupled short codes. Because complexity of decoding the short codes, decoding complexity is low.

In a possible implementation, no overlapping element exists in the first matrix block and the second matrix block.

In a possible implementation, a size of the first generator matrix is v*v, and an element in the first generator matrix satisfies a_{i,j}=a_{i+u,j+u}, where i is an integer, j is an integer, v is a positive integer, u is an integer, 1≤i<v, 1≤j<v, 1<i+u≤v, and 1<j+u≤v.

In the foregoing process, when the first generator matrix satisfies a_{i,j}=a_{i+u,j+u}, the first generator matrix satisfies the self-similarity. Polar decoding the K to-be-decoded bits based on the second generator matrix is equivalent to: polar decoding a plurality of short codes, and coupling the plurality of short codes, to obtain a decoding result. This can reduce decoding complexity.

In a possible implementation, elements in the first generator matrix are symmetrical along a secondary diagonal of the first generator matrix.

In the foregoing process, because the elements in the first generator matrix are symmetrical along the secondary diagonal of the first generator matrix, decoding complexity is low.

In a possible implementation, T is a minimum integer that enables a first condition to be satisfied, and the first condition is that a size of the second generator matrix is greater than or equal to a decoding length.

In a possible implementation, T satisfies the following relationship: v+(T−1)*u<N′≤v+T*u, v is the size of the first generator matrix, N′ is the decoding length, and N′ is an integer greater than 1.

In the foregoing process, an excessively large or small size of the second generator matrix may be avoided, and therefore decoding complexity is low.

In a possible implementation, the bit information includes N′ first log-likelihood ratio LLR sequences, where N′ is a positive integer.

In a possible implementation, the N′ first LLRs include T first LLR sequences, and the first LLR sequence includes at least two first LLRs. Polar decoding includes: determining T second LLR sequences corresponding to the T first LLR sequences, where one of the first LLR sequences corresponds to one or more groups of unencoded bits, and one of the second LLR sequences corresponds to one group of unencoded bits; and performing polar decoding based on the T second LLR sequences.

In the foregoing process, the T coupled first LLR sequences are first decoupled to obtain the T decoupled second LLR sequences, and then the T decoupled second LLR sequences are decoded. Because a length of the second LLR sequence is small, complexity of decoding the second LLR sequence is low, and decoding complexity is low.

In a possible implementation, the determining T second LLR sequences corresponding to the T first LLR sequences includes: determining an i^{th} second LLR sequence based on an i^{th} first LLR sequence and at least one of first (i−1) second LLR sequences, where i is an integer between 2 and T.

In the foregoing process, when the i^{th} second LLR sequence is determined, the first LLR sequences are decoupled based on the i^{th} first LLR sequence and the at least one of the decoupled first (i−1) second LLR sequences, to obtain the i^{th} second LLR sequence.

In a possible implementation, a coupling degree of a code block is 2. The determining an i^{th} second LLR sequence based on an i^{th} first LLR sequence and at least one of first (i−1) second LLR sequences includes: determining the i^{th} second LLR sequence based on the i^{th} first LLR sequence and an (i−1)^{th} second LLR sequence.

In a possible implementation, a 1^{st} second LLR sequence is the same as a 1^{st} first LLR sequence.

In a possible implementation, a coupling degree of a code block is 4. The determining an i^{th} second LLR sequence based on an i^{th} first LLR sequence and at least one of first (i−1) second LLR sequences includes: determining the i^{th} second LLR sequence based on the i^{th} first LLR sequence and an (i−2)^{th} second LLR sequence, where i is an integer between 3 and T.

In a possible implementation, a 1^{st} second LLR sequence is the same as a 1^{st} first LLR sequence, and a 2^{nd} second LLR sequence is the same as a 2^{nd} first LLR sequence.

In a possible implementation, polar decoding may be performed based on the T second LLR sequences in the following manner: determining to obtain a T^{th} decoding result based on a T^{th} second LLR sequence; and determining an i^{th} decoding result based on the i^{th} second LLR sequence and at least one of an (i+1)^{th} decoding result to the T^{th} decoding result, where i is an integer between 1 and T−1.

In the foregoing process, the second LLR sequence (short code) is decoded to obtain a decoding result, and therefore decoding complexity is low.

In a possible implementation, a coupling degree of a code block is 2. The determining an i^{th} decoding result based on the i^{th} second LLR sequence and at least one of an (i+1)^{th} decoding result to the T^{th} decoding result includes: determining the i^{th} decoding result based on the (i+1)^{th} decoding result, an (i+1)^{th} first LLR sequence, and the i^{th} second LLR sequence.

According to a fifth aspect, an embodiment of this application provides an encoding apparatus, including an obtaining module, a determining module, a generation module, and an encoding module.

The obtaining module is configured to obtain K to-be-encoded bits, where K is a positive integer.

The determining module is configured to determine a first generator matrix. The first generator matrix includes at least two sub-blocks distributed based on a preset position relationship, and the sub-block includes a plurality of first generator matrix cores.

The generation module is configured to generate a second generator matrix based on the first generator matrix. The second generator matrix includes T sub-blocks, and a position relationship between two adjacent sub-blocks of the T sub-blocks is determined based on the preset position relationship, where T is a positive integer.

The encoding module is configured to polar encode the K to-be-encoded bits based on the second generator matrix, to obtain encoded bits.

In a possible implementation, the position relationship between two adjacent sub-blocks of the T sub-blocks is the same as the preset position relationship.

In a possible implementation, an overlapping portion exists in the at least two sub-blocks.

In a possible implementation, a first diagonal of the sub-block includes the first generator matrix cores.

In a possible implementation, the plurality of first generator matrix cores in the sub-block are distributed in a lower triangular form.

In a possible implementation, distribution of the first generator matrix cores in the sub-block is the same as distribution of first elements in a second generator matrix core, a quantity of elements included in the second generator matrix core is the same as a quantity of sub-matrices included in the sub-block, and a sub-matrix included in the sub-block is the first generator matrix core or a zero matrix.

In a possible implementation, the first generator matrix includes two sub-blocks.

In a possible implementation, the quantity of sub-matrices included in the sub-block is 2*2, and the sub-matrix included in the sub-block is the first generator matrix core or the zero matrix.

In a possible implementation, the first generator matrix includes a first sub-block and a second sub-block, and a first sub-matrix in the first sub-block overlaps a second sub-matrix in the second sub-block; and coordinates of the first sub-matrix in the first sub-block are (2, 2), and coordinates of the second sub-matrix in the second sub-block are (1, 1).

In a possible implementation, the quantity of sub-matrices included in the sub-block is 4*4, and the sub-matrix included in the sub-block is the first generator matrix core or the zero matrix.

In a possible implementation, the first generator matrix includes a first sub-block and a second sub-block, and four first sub-matrices in the first sub-block overlap four second sub-matrices in the second sub-block.

Coordinates of the four first sub-matrices in the first sub-block are (3, 3), (3, 4), (4, 3), and (4, 4); and
coordinates of the four second sub-matrices in the second sub-block are (1, 1), (1, 2), (2, 1), and (2, 2).

In a possible implementation, the K to-be-encoded bits are information bits. The encoding module is specifically configured to:
determine K sub-channels with highest reliability in a plurality of sub-channels corresponding to the K to-be-encoded bits;
determine positions of the K to-be-encoded bits based on the K sub-channels with the highest reliability;
determine a to-be-encoded sequence based on the positions of the K to-be-encoded bits, where the to-be-encoded sequence comprises the K to-be-encoded bits and frozen bits; and
polar encode the to-be-encoded sequence based on the second generator matrix, to obtain the encoded bits.

In a possible implementation, the plurality of sub-channels include P groups of sub-channels, where P is a positive integer. The encoding module is specifically configured to:
determine Xᵢ first sub-channels from an i^{th} group of sub-channels based on reliability of the i^{th} group of sub-channels, where the Xᵢ first sub-channels are Xᵢ sub-channels with highest reliability in the i^{th} group of sub-channels, i is an integer, 1≤i≤P, Xᵢ is a positive integer, and Σᵢ₌₁^{i=P} Xᵢ=K.

The K sub-channels with the highest reliability include the first sub-channels.

According to a sixth aspect, an embodiment of this application provides a decoding apparatus, including a receiving module and a decoding module.

The receiving module is configured to receive polar encoded bit information.

The decoding module is configured to polar decode the bit information based on a second generator matrix, to obtain polar decoded bits.

The second generator matrix is generated based on a first generator matrix, the first generator matrix includes at least two sub-blocks distributed based on a preset position relationship, the sub-block includes a plurality of first generator matrix cores, the second generator matrix includes T sub-blocks, and a position relationship between two adjacent sub-blocks of the T sub-blocks is determined based on the preset position relationship, where T is a positive integer.

In a possible implementation, the position relationship between two adjacent sub-blocks of the T sub-blocks is the same as the preset position relationship.

In a possible implementation, an overlapping portion exists in the at least two sub-blocks.

In a possible implementation, a first diagonal of the sub-block includes the first generator matrix cores.

In a possible implementation, the plurality of first generator matrix cores in the sub-block are distributed in a lower triangular form.

In a possible implementation, distribution of the first generator matrix cores in the sub-block is the same as distribution of first elements in a second generator matrix core, a quantity of elements included in the second generator matrix core is the same as a quantity of elements included in the sub-block, and an element included in the sub-block is the first generator matrix core or a zero matrix.

In a possible implementation, the first generator matrix includes two sub-blocks.

In a possible implementation, the quantity of elements included in the sub-block is 2*2, and the element included in the sub-block is the first generator matrix core or the zero matrix.

In a possible implementation, the first generator matrix includes a first sub-block and a second sub-block, and a first element in the first sub-block overlaps a second element in the second sub-block; and
coordinates of the first element in the first sub-block are (2, 2), and coordinates of the second element in the second sub-block are (1, 1).

In a possible implementation, the quantity of elements included in the sub-block is 4*4, and the element included in the sub-block is the first generator matrix core or the zero matrix.

In a possible implementation, the first generator matrix includes a first sub-block and a second sub-block, and four first elements in the first sub-block overlap four second elements in the second sub-block.

Coordinates of the four first elements in the first sub-block are (3, 3), (3, 4), (4, 3), and (4, 4); and
coordinates of the four second elements in the second sub-block are (1, 1), (1, 2), (2, 1), and (2, 2).

In a possible implementation, the bit information includes N′ first log-likelihood ratio LLR sequences, where N′ is a positive integer.

In a possible implementation, the N′ first LLRs include T first LLR sequences, and the first LLR sequence includes at least two first LLRs. The decoding module is specifically configured to:
determine T second LLR sequences corresponding to the T first LLR sequences, where one of the first LLR sequences corresponds to one or more groups of unencoded bits, and one of the second LLR sequences corresponds to one group of unencoded bits; and
perform polar decoding based on the T second LLR sequences.

In a possible implementation, the decoding module is specifically configured to:
determine an i^{th} second LLR sequence based on an i^{th} first LLR sequence and at least one of first (i−1) second LLR sequences, where i is an integer between 2 and T.

In a possible implementation, a coupling degree of a code block is 2. The decoding module is specifically configured to:
determine the i^{th} second LLR sequence based on the i^{th} first LLR sequence and an (i−1)^{th} second LLR sequence.

In a possible implementation, a 1^{st} second LLR sequence is the same as a 1^{st} first LLR sequence.

In a possible implementation, a coupling degree of a code block is 4. The decoding module is specifically configured to:
determine the i^{th} second LLR sequence based on the i^{th} first LLR sequence and an (i−2)^{th} second LLR sequence, where i is an integer between 3 and T.

In a possible implementation, a 1^{st} second LLR sequence is the same as a 1^{st} first LLR sequence; and
a 2^{nd} second LLR sequence is the same as a 2^{nd} first LLR sequence.

In a possible implementation, the decoding module is specifically configured to:
determine to obtain a T^{th} decoding result based on a T^{th} second LLR sequence; and
determine an i^{th} decoding result based on the i^{th} second LLR sequence and at least one of an (i+1)^{th} decoding result to the T^{th} decoding result, where i is an integer between 1 and T−1.

In a possible implementation, a coupling degree of a code block is 2. The decoding module is specifically configured to:
determine the i^{th} decoding result based on the (i+1)^{th} decoding result, an (i+1)^{th} first LLR sequence, and the i^{th} second LLR sequence.

According to a seventh aspect, an embodiment of this application provides an encoding apparatus, including an obtaining module, a determining module, a generation module, and an encoding module.

The obtaining module is configured to obtain K to-be-encoded bits, where K is a positive integer.

The determining module is configured to determine a first generator matrix. The first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1.

The generation module is configured to generate a second generator matrix based on an encoding length and the first generator matrix. The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

The encoding module is configured to polar encode the K to-be-encoded bits based on the second generator matrix, to obtain encoded bits.

In a possible implementation, no overlapping element exists in the first matrix block and the second matrix block.

In a possible implementation, a size of the first generator matrix is v*v, and an element in the first generator matrix satisfies a_{i,j}=a_{i+u,j+u}, where
i is an integer, j is an integer, v is a positive integer, u is an integer, 1≤i<v, 1≤j<v, 1<i+u≤v, and 1<j+u≤V.

In a possible implementation, elements in the first generator matrix are symmetrical along a secondary diagonal of the first generator matrix.

In a possible implementation, T is a minimum integer that enables a first condition to be satisfied, and the first condition is that a size of the second generator matrix is greater than or equal to the encoding length.

In a possible implementation, T satisfies the following relationship:

v+(T−1)*u<N′≤v+T*u, where
v is the size of the first generator matrix, N′ is the encoding length, and N′ is an integer greater than 1.

According to an eighth aspect, an embodiment of this application provides a decoding apparatus, including a receiving module and a decoding module.

The receiving module is configured to receive polar encoded bit information.

The decoding module is configured to polar decode the bit information based on a second generator matrix, to obtain polar decoded bits. The second generator matrix is generated based on a first generator matrix.

The first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1.

The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

In a possible implementation, no overlapping element exists in the first matrix block and the second matrix block.

In a possible implementation, a size of the first generator matrix is v*v, and an element in the first generator matrix satisfies a_{i,j}=a_{i+u,j+u}, where
i is an integer, j is an integer, v is a positive integer, u is an integer, 1≤i<v, 1≤j<v, 1<i+u≤v, and 1<j+u≤v.

In a possible implementation, elements in the first generator matrix are symmetrical along a secondary diagonal of the first generator matrix.

In a possible implementation, T is a minimum integer that enables a first condition to be satisfied, and the first condition is that a size of the second generator matrix is greater than or equal to the encoding length.

In a possible implementation, T satisfies the following relationship:

v+(T−1)*u<N′≤v+T*u, where
v is the size of the first generator matrix, N′ is the encoding length, and N′ is an integer greater than 1.

In a possible implementation, the bit information includes N′ first log-likelihood ratio LLR sequences, where N′ is a positive integer.

In a possible implementation, the N′ first LLRs include T first LLR sequences, and the first LLR sequence includes at least two first LLRs. The decoding module is specifically configured to:
determine T second LLR sequences corresponding to the T first LLR sequences, where one of the first LLR sequences corresponds to one or more groups of unencoded bits, and one of the second LLR sequences corresponds to one group of unencoded bits; and
perform polar decoding based on the T second LLR sequences.

In a possible implementation, the decoding module is specifically configured to:
determine an i^{th} second LLR sequence based on an i^{th} first LLR sequence and at least one of first (i−1) second LLR sequences, where i is an integer between 2 and T.

In a possible implementation, a coupling degree of a code block is 2. The decoding module is specifically configured to:
determine the i^{th} second LLR sequence based on the i^{th} first LLR sequence and an (i−1)^{th} second LLR sequence.

In a possible implementation, a 1^{st} second LLR sequence is the same as a 1^{st} first LLR sequence.

In a possible implementation, a coupling degree of a code block is 4. The decoding module is specifically configured to:
determine the i^{th} second LLR sequence based on the i^{th} first LLR sequence and an (i−2)^{th} second LLR sequence, where i is an integer between 3 and T.

In a possible implementation, a 1^{st} second LLR sequence is the same as a 1^{st} first LLR sequence; and
a 2^{nd} second LLR sequence is the same as a 2^{nd} first LLR sequence.

In a possible implementation, the decoding module is specifically configured to:
determine to obtain a T^{th} decoding result based on a T^{th} second LLR sequence; and
determine an i^{th} decoding result based on the i^{th} second LLR sequence and at least one of an (i+1)^{th} decoding result to the T^{th} decoding result, where i is an integer between 1 and T−1.

In a possible implementation, a coupling degree of a code block is 2. The decoding module is specifically configured to:
determine the i^{th} decoding result based on the (i+1)^{th} decoding result, an (i+1)^{th} first LLR sequence, and the i^{th} second LLR sequence.

According to a ninth aspect, an embodiment of this application provides an encoding apparatus, including a memory, a processor, and a computer program. The computer program is stored in the memory, and the processor runs the computer program to perform the encoding method according to any implementation of the first aspect.

According to a tenth aspect, an embodiment of this application provides an encoding apparatus, including a memory, a processor, and a computer program. The computer program is stored in the memory, and the processor runs the computer program to perform the decoding method according to any implementation of the second aspect.

According to an eleventh aspect, an embodiment of this application provides an encoding apparatus, including a memory, a processor, and a computer program. The computer program is stored in the memory, and the processor runs the computer program to perform the encoding method according to any implementation of the third aspect.

According to a twelfth aspect, an embodiment of this application provides an encoding apparatus, including a memory, a processor, and a computer program. The computer program is stored in the memory, and the processor runs the computer program to perform the decoding method according to any implementation of the fourth aspect.

According to a thirteenth aspect, an embodiment of this application provides a storage medium. The storage medium includes a computer program, and the computer program is used to perform the encoding method according to any implementation of the first aspect.

According to a fourteenth aspect, an embodiment of this application provides a storage medium. The storage medium includes a computer program, and the computer program is used to perform the decoding method according to any implementation of the second aspect.

According to a fifteenth aspect, an embodiment of this application provides a storage medium. The storage medium includes a computer program, and the computer program is used to perform the encoding method according to any implementation of the third aspect.

According to a sixteenth aspect, an embodiment of this application provides a storage medium. The storage medium includes a computer program, and the computer program is used to perform the decoding method according to any implementation of the fourth aspect.

According to a seventeenth aspect, an embodiment of this application provides an encoding apparatus. The encoding apparatus may include an input interface and a logic circuit.

The input interface is configured to obtain K to-be-encoded bits, where K is a positive integer.

The logic circuit is configured to: determine a first generator matrix, where the first generator matrix includes at least two sub-blocks distributed based on a preset position relationship, and the sub-block includes a plurality of first generator matrix cores; generate a second generator matrix based on the first generator matrix, where the second generator matrix includes T sub-blocks, and a position relationship between two adjacent sub-blocks of the T sub-blocks is determined based on the preset position relationship, where T is a positive integer; and polar encode the K to-be-encoded bits based on the second generator matrix, to obtain encoded bits.

In a possible implementation, the logic circuit may further perform the encoding method according to any implementation of the first aspect.

According to an eighteenth aspect, an embodiment of this application provides a decoding apparatus. The decoding apparatus may include an input interface and a logic circuit.

The input interface is configured to receive polar encoded bit information.

The logic circuit is configured to polar decode the bit information based on a second generator matrix, to obtain polar decoded bits. The second generator matrix is generated based on a first generator matrix, the first generator matrix includes at least two sub-blocks distributed based on a preset position relationship, the sub-block includes a plurality of first generator matrix cores, the second generator matrix includes T sub-blocks, and a position relationship between two adjacent sub-blocks of the T sub-blocks is determined based on the preset position relationship, where T is a positive integer.

In a possible implementation, the logic circuit may further perform the decoding method according to any implementation of the second aspect.

According to a nineteenth aspect, an embodiment of this application provides a schematic diagram of a structure of an encoding apparatus. The encoding apparatus may include an input interface and a logic circuit.

The input interface is configured to obtain K to-be-encoded bits, where K is a positive integer.

The logic circuit is configured to: determine a first generator matrix, where the first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1; determine a second generator matrix based on an encoding length and the first generator matrix, where the second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2; and polar encode the K to-be-encoded bits based on the second generator matrix, to obtain encoded bits.

In a possible implementation, the logic circuit may further perform the encoding method according to any implementation of the third aspect.

According to a twentieth aspect, an embodiment of this application provides a decoding apparatus. The decoding apparatus may include an input interface and a logic circuit.

The input interface is configured to receive polar encoded bit information.

The logic circuit is configured to polar decode the bit information based on a second generator matrix, to obtain polar decoded bit. The second generator matrix is generated based on a first generator matrix, the first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1. The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

In a possible implementation, the logic circuit may further perform the decoding method according to any implementation of the fourth aspect.

Embodiments of this application provide the encoding method and apparatus, the decoding method and apparatus, and the device. When the K to-be-encoded bits need to be encoded, the first generator matrix is first determined, then the second generator matrix is generated based on the first generator matrix, and the K to-be-encoded bits are polar encoded based on the second generator matrix. The first generator matrix includes the at least two sub-blocks distributed based on the preset position relationship, each sub-block includes a plurality of first generator matrix cores, the second generator matrix includes the T sub-blocks, and the position relationship between two adjacent sub-blocks of the T sub-blocks is determined based on the preset position relationship. Therefore, it may be learned that the second generator matrix includes a plurality of sub-blocks arranged according to the foregoing preset position relationship, and each sub-block includes a plurality of first generator matrix cores. Therefore, polar encoding the K to-be-encoded bits based on the second generator matrix is equivalent to: polar encoding a plurality of short codes, and coupling the plurality of short codes to obtain an encoding result. This can reduce encoding complexity. When a codeword obtained encoding based on the foregoing encoding method is decoded, decoding complexity can be reduced.

### BRIEF DESCRIPTION OF DRAWINGS

FIG. 1 is an architectural diagram of a communication system according to this application;

FIG. 2 is a diagram of encoding according to an embodiment of this application;

FIG. 3 is a schematic flowchart of an encoding method according to an embodiment of this application;

FIG. 4 is a schematic diagram of a sub-block according to an embodiment of this application;

FIG. 5A is a schematic diagram of a first generator matrix according to an embodiment of this application;

FIG. 5B is a schematic diagram of another first generator matrix according to an embodiment of this application;

FIG. 5C is a schematic diagram of still another first generator matrix according to an embodiment of this application;

FIG. 6A is a schematic diagram of a second generator matrix according to an embodiment of this application;

FIG. 6B is a schematic diagram of another second generator matrix according to an embodiment of this application;

FIG. 6C is a schematic diagram of still another second generator matrix according to an embodiment of this application;

FIG. 7A is a schematic diagram of a third generator matrix according to an embodiment of this application;

FIG. 7B is a schematic diagram of another third generator matrix according to an embodiment of this application;

FIG. 8A is a schematic diagram of a decoding process according to an embodiment of this application;

FIG. 8B is a schematic diagram of another decoding process according to an embodiment of this application;

FIG. 9A is another diagram of encoding according to an embodiment of this application;

FIG. 9B is still another diagram of encoding according to an embodiment of this application;

FIG. 9C is yet another diagram of encoding according to an embodiment of this application;

FIG. 10 is a schematic flowchart of another encoding method according to an embodiment of this application;

FIG. 11A is a schematic diagram of yet another first generator matrix according to an embodiment of this application;

FIG. 11B is a schematic diagram of still yet another first generator matrix according to an embodiment of this application;

FIG. 11C is a schematic diagram of a further first generator matrix according to an embodiment of this application;

FIG. 12A is a schematic diagram of a still further first generator matrix according to an embodiment of this application;

FIG. 12B is a schematic diagram of a yet further first generator matrix according to an embodiment of this application;

FIG. 13 is a schematic diagram of yet another second generator matrix according to an embodiment of this application;

FIG. 14 is a schematic diagram of a process of generating a second generator matrix according to an embodiment of this application;

FIG. 15A is a schematic diagram of still yet another second generator matrix according to an embodiment of this application;

FIG. 15B is a schematic diagram of a further second generator matrix according to an embodiment of this application;

FIG. 15C is a schematic diagram of a still further second generator matrix according to an embodiment of this application;

FIG. 16 is a schematic diagram of decoding according to an embodiment of this application;

FIG. 17 is a schematic diagram of a decoding process according to an embodiment of this application;

FIG. 18 is a schematic diagram of another decoding process according to an embodiment of this application;

FIG. 19 is a schematic diagram of decoding performance according to an embodiment of this application;

FIG. 20A is another schematic diagram of decoding performance according to an embodiment of this application;

FIG. 20B is still another schematic diagram of decoding performance according to an embodiment of this application;

FIG. 21 is a schematic diagram of a structure of an encoding apparatus according to an embodiment of this application;

FIG. 22 is a schematic diagram of a structure of a decoding apparatus according to an embodiment of this application;

FIG. 23 is a schematic diagram of a structure of another encoding apparatus according to an embodiment of this application;

FIG. 24 is a schematic diagram of a structure of another decoding apparatus according to an embodiment of this application;

FIG. 25 is a schematic diagram of a hardware structure of still another encoding apparatus according to an embodiment of this application;

FIG. 26 is a schematic diagram of a hardware structure of still another decoding apparatus according to an embodiment of this application;

FIG. 27 is a schematic diagram of a structure of yet another encoding apparatus according to an embodiment of this application;

FIG. 28 is a schematic diagram of a structure of yet another decoding apparatus according to an embodiment of this application;

FIG. 29 is a schematic diagram of a structure of still yet another encoding apparatus according to an embodiment of this application; and

FIG. 30 is a schematic diagram of a structure of still yet another decoding apparatus according to an embodiment of this application.

### DESCRIPTION OF EMBODIMENTS

Embodiments of this application may be used in various fields in which polar coding is used, for example, a data storage field, an optical network communication field, and a wireless communication field. A wireless communication system mentioned in embodiments of this application includes but is not limited to a narrowband internet of things (NB-IoT) system, a WiMAX system, a long term evolution (LTE) system, and three application scenarios of a next-generation 5G mobile communication system new radio (NR): enhanced mobile broadband (eMBB), ultra-reliable and low-latency communication (URLLC), and massive machine-to-machine communications (mMTC). Certainly, there may be another field in which polar coding is used. This is not specifically limited in this application. Embodiments of this application are applicable to a communication scenario with a long code length, for example, including but not limited to a service scenario with a large throughput, a high-definition video service scenario, a large file transfer service scenario, and a multimedia service such as virtual reality (VR)/augmented reality (AR for short), and hybrid automatic repeat request (HARQ) for wireless communication.

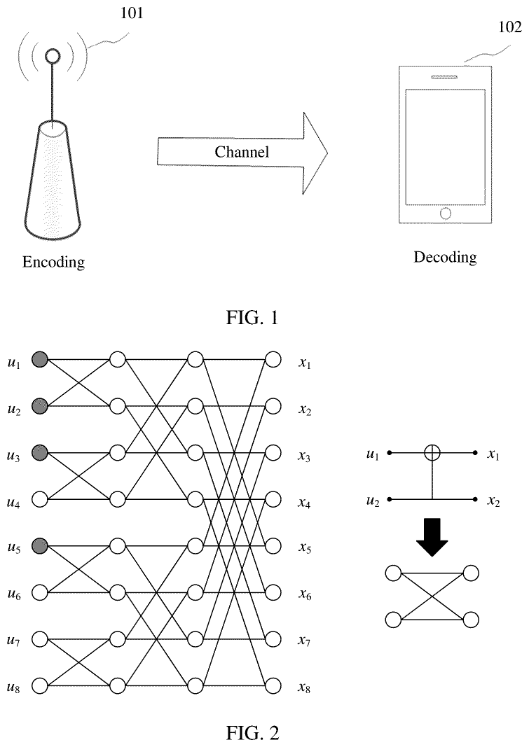

For ease of understanding, the following describes, with reference to FIG. 1, an architectural diagram of a communication system to which embodiments of this application are applicable.

FIG. 1 is an architectural diagram of a communication system according to this application. Refer to FIG. 1. A sending device 101 and a receiving device 102 are included.

Optionally, when the sending device 101 is a terminal device, the receiving device 102 is a network device. When the sending device 101 is a network device, the receiving device 102 is a terminal device.

Refer to FIG. 1. The sending device 101 includes an encoder, so that the sending device 101 can perform polar encoding and output an encoded sequence. After being rate matched, interleaved, and modulated, the encoded sequence is transmitted to the receiving device 102 through a channel. The receiving device 102 includes a decoder. The receiving device 102 may receive a signal sent by the sending device 101, and decode the received signal.

It should be noted that FIG. 1 is merely an example of an architectural diagram of a communication system, and does not limit the architectural diagram of the communication system.

For ease of understanding, the following describes concepts in embodiments of this application.

A terminal device includes but is not limited to a mobile station (MS), a mobile terminal (MT), a mobile phone (handset), portable equipment (portable equipment), and the like. The terminal device may communicate with one or more core networks through a radio access network (RAN). For example, the terminal device may be a mobile phone (or referred to as a “cellular” phone), a computer having a wireless communication function, or the like. Alternatively, the terminal device may be a portable, pocket-sized, handheld, computer built-in, or in-vehicle mobile apparatus or device.

A network device may be an evolved NodeB (eNB or eNodeB) in an LTE system; a network device may be a gNB, a transmission reception point (TRP), a micro base station, or the like in a 5G communication system; a network device may be a relay station, an access point, an in-vehicle device, a wearable device, or a network device in a future evolved public land mobile network (PLMN), a base station in another network integrating a plurality of technologies, a base station in various other evolved networks, or the like.

Polar coding: Polar coding may alternatively be polar encoding/decoding, and polar coding may be described in the following two manners:

In a manner, an encoding process may be expressed by using a generator matrix, that is, x₁^{N}=u₁^{N}G_{N}.
u₁^{N} is a row vector, u₁^{N}=(u₁, u₂, . . . , u_{N}), N is a code length, N is an integer greater than or equal to 1, uᵢ is an unencoded bit, i is an integer between 1 and N, u₁^{N} includes information bits and/or frozen bits, that is, uᵢ may be the information bit or the frozen bit. The information bit is a bit used to carry information, and the information bit may include a cyclic redundancy check (CRC) bit and/or a parity check (PC) bit. The frozen bit is a padding bit, and the frozen bit may be usually 0.

G_{N} is a generator matrix, G_{N} is an N*N matrix, and G_{N}=B_{N}F₂^{⊗(log}^{₂}^{(N))}, where B_{N} is an N*N reversal matrix, for example, B_{N} may be a bit reversal (bit reversal) matrix,

$${F}_{2} = [ \begin{matrix}1 & 0 \\ 1 & 1\end{matrix} ] ,$$

F₂^{⊗(log}^{₂}^{(N))} is a Kronecker (Kronecker) product of log₂(N) matrices F₂. Both addition and multiplication above are operations in the binary Galois field (Galois field). G_{N} may also be referred to as a generator matrix core.

In another manner, the encoding process may be expressed by using a diagram of encoding.

The following describes the diagram of encoding with reference to FIG. 2.

FIG. 2 is a diagram of encoding according to an embodiment of this application. Refer to FIG. 2. An encoding length corresponding to the diagram of encoding is 8, each circle in a first column represents one information bit or frozen bit, and u₁, u₂, . . . , u₈ shown in the first column are unencoded bits (information bits or frozen bits), where u₄, u₆, u₇, u₈ are information bits, and u₁, u₂, u₃, u₅ are frozen bits. Each circle in columns other than the first column represents one partial sum (partial sum) bit. x₁, x₂, . . . , x₈ in a last column are encoded bits. Each butterfly diagram (shown on the right side of the figure) represents one polarization of two bits, that is, x₁²=u₁²G₂.

In a polar encoding process, a larger code length indicates higher encoding complexity. For example, complexity of polar encoding in a current technology is O(N*log₂(N)). To resolve this technical problem, an embodiment of this application provides an encoding method. In an encoding process, a generator matrix corresponding to short codes may be processed to obtain a final generator matrix, and polar encoding is performed based on the final generator matrix. This is equivalent to: polar encoding the plurality of short codes, and coupling the plurality of short codes, to obtain an encoding result. This can reduce encoding complexity.

When encoding is performed based on the final generator matrix, the encoding complexity can be reduced.

It should be noted that, in this embodiment of this application, an example in which start coordinates (the coordinates at the topmost-left corner) in the matrix are (1, 1) is used for description. Certainly, the start coordinates in the matrix may alternatively be (0, 0). This is not specifically limited in this embodiment of this application.

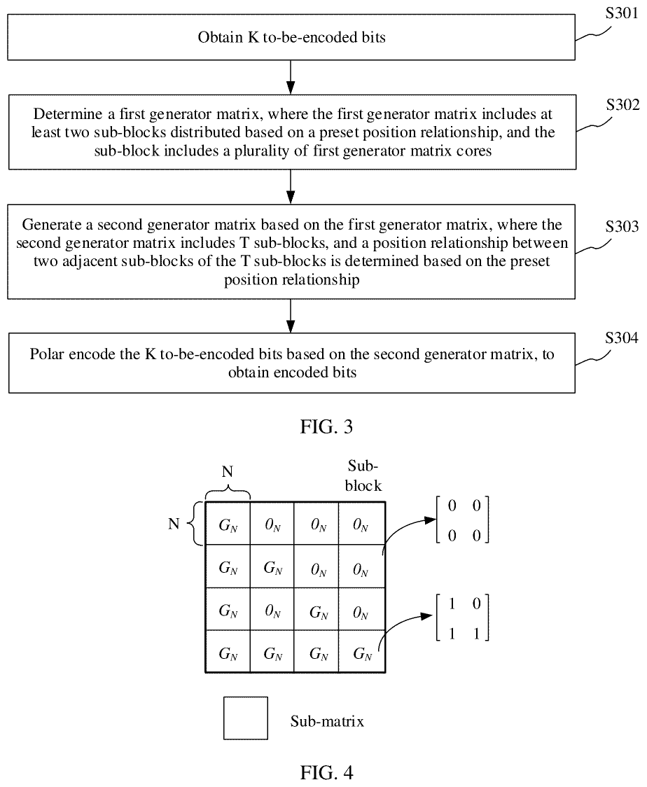

FIG. 3 is a schematic flowchart of an encoding method according to an embodiment of this application. Refer to FIG. 3. The method may include the following steps.

S301: Obtain K to-be-encoded bits.

K is a positive integer.

Optionally, the K to-be-encoded bits include information bits and frozen bits. Alternatively, all of the K to-be-encoded bits are information bits.

S302: Determine a first generator matrix.

The first generator matrix includes at least two sub-blocks distributed based on a preset position relationship, and the sub-block includes a plurality of first generator matrix cores.

The first generator matrix core may be G_{N}, where N=2ⁿ, and n is a positive integer. In an actual application process, a value of N may be set according to an actual requirement. For example, N may be a preset value.

The sub-block may include the first generator matrix cores and zero matrices (which may be expressed as 0_{N}). A size of the first generator matrix core is the same as a size of the zero matrix. For example, if the size of the first generator matrix core is N*N, the size of the zero matrix is also N*N. For ease of description, in the following, the first generator matrix core or the zero matrix is referred to as a sub-matrix.

It should be noted that, in this embodiment of this application, a size of a matrix means that the matrix includes a row quantity and a column quantity, and the size of the matrix may be expressed by M*N (M is the row quantity of the matrix, and N is the column quantity of the matrix). When the matrix is a square matrix (square matrix), the size of the matrix may be expressed by the row quantity or the column quantity. For example, when the matrix includes N rows and N columns, the size of the matrix may be expressed by N*N, or the size of the matrix may be expressed by N. The following describes the sub-block with reference to FIG. 4.

FIG. 4 is a schematic diagram of the sub-block according to this embodiment of this application. Refer to FIG. 4. The sub-block includes a plurality of sub-matrices. In FIG. 4, an example in which a quantity of sub-matrices is 16 is used for description. Each sub-matrix includes N*N elements. For example, the element may be 0 or 1. The sub-matrix may be G_{N} or 0_{N}. If N is equal to 2,

$${G}_{N} = [ \begin{matrix}1 & 0 \\ 1 & 1\end{matrix} ] , and {0}_{N} = [ \begin{matrix}0 & 0 \\ 0 & 0\end{matrix} ] .$$

Optionally, first generator matrix cores (G_{N}) are included on a first diagonal of the sub-block. The first diagonal may be a main diagonal of the sub-block. For example, refer to FIG. 4. Sub-matrices located on the main diagonal of the sub-block are G_{N}, for example, sub-matrices at coordinates (1, 1), (2, 2), (3, 3), and (4, 4) are G_{N}.

Optionally, the plurality of first generator matrix cores in the sub-block are distributed in a lower triangular form. For example, refer to FIG. 4. A plurality of G_{N} in the sub-block are distributed in a lower triangular form.

Optionally, distribution of the first generator matrix cores in the sub-block is the same as distribution of first elements in a second generator matrix core. The first element may be 1. Distribution of elements in the second generator matrix core satisfies B_{N}F₂^{⊗(log}^{₂}^{(N))}, and a quantity of elements in the second generator matrix core may be the same as or different from a quantity of elements in the first generator matrix core. For example, if the second generator matrix core is

$$[ \begin{matrix}1 & 0 & 0 & 0 \\ 1 & 1 & 0 & 0 \\ 1 & 0 & 1 & 0 \\ 1 & 1 & 1 & 1\end{matrix} ] ,$$

and the sub-block is shown in FIG. 4, distribution of G_{N} in the sub-blocks is the same as distribution of 1s in the second generator matrix core, and distribution of 0_{N} in the sub-block is correspondingly the same as distribution of 0s in the second generator matrix core.

The following describes the sub-block by using a specific example.

Example 1: If the second generator matrix core is

$$[ \begin{matrix}1 & 0 \\ 1 & 1\end{matrix} ] ,$$

the sub-block may be

$$[ \begin{matrix}{G}_{N} & {0}_{N} \\ {G}_{N} & {G}_{N}\end{matrix} ] ,$$

and a quantity of sub-matrices included in the sub-block is 2*2. Distribution of G_{N} in the sub-blocks is the same as distribution of elements 1 in the second generator matrix core.

If N=2,

$${G}_{N} = [ \begin{matrix}1 & 0 \\ 1 & 1\end{matrix} ] .$$

$$[ \begin{matrix}1 & 0 \\ 1 & 1\end{matrix} ]$$

is substituted into G_{N} in the sub-block, to obtain the sub-block as

$$[ \begin{matrix}1 & 0 & 0 & 0 \\ 1 & 1 & 0 & 0 \\ 1 & 0 & 1 & 0 \\ 1 & 1 & 1 & 1\end{matrix} ] .$$

If N=4,

$${G}_{N} = [ \begin{matrix}1 & 0 & 0 & 0 \\ 1 & 1 & 0 & 0 \\ 1 & 0 & 1 & 0 \\ 1 & 1 & 1 & 1\end{matrix} ] .$$

$$[ \begin{matrix}1 & 0 & 0 & 0 \\ 1 & 1 & 0 & 0 \\ 1 & 0 & 1 & 1 \\ 1 & 1 & 1 & 1\end{matrix} ]$$

is substituted into G_{N} in the sub-block, to obtain the sub-block as

$$[ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] .$$

Example 2: If the second generator matrix core is

$$[ \begin{matrix}1 & 0 & 0 & 0 \\ 1 & 1 & 0 & 0 \\ 1 & 0 & 1 & 0 \\ 1 & 1 & 1 & 1\end{matrix} ] ,$$

the sub-block may be

$$[ \begin{matrix}{G}_{N} & {0}_{N} & {0}_{N} & {0}_{N} \\ {G}_{N} & {G}_{N} & {0}_{N} & {0}_{N} \\ {G}_{N} & {0}_{N} & {G}_{N} & {0}_{N} \\ {G}_{N} & {G}_{N} & {G}_{N} & {G}_{N}\end{matrix} ] ,$$

and distribution of G_{N} in the sub-block is the same as distribution of elements 1 in the second generator matrix core.

If N=2,

$${G}_{N} = [ \begin{matrix}1 & 0 \\ 1 & 1\end{matrix} ] .$$

$$[ \begin{matrix}1 & 0 \\ 1 & 1\end{matrix} ]$$

is substituted into G_{N} in the sub-block, to obtain the sub-block as

$$[ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] .$$

The first generator matrix includes the at least two sub-blocks distributed based on the preset position relationship. Optionally, a quantity of sub-blocks included in the first generator matrix may be 2.

Optionally, an overlapping portion exists in the at least two sub-blocks in the first generator matrix. For example, an overlapping portion exists in every two adjacent sub-blocks in the first generator matrix. If the two adjacent sub-blocks are a sub-block 1 and a sub-block 2, an element in the bottom-right corner area of the sub-block 1 overlaps an element in the top-left corner area of the sub-block 2.

For example, when the first generator matrix includes two sub-blocks (denoted as the sub-block 1 and the sub-block 2), the preset position relationship may be: The sub-block 1 is located on the top-left portion of the first generator matrix, the sub-block 2 is located on the bottom-right port of the first generator matrix, and the bottom-right corner area of the sub-block 1 overlaps the top-left corner area of the sub-block 2.

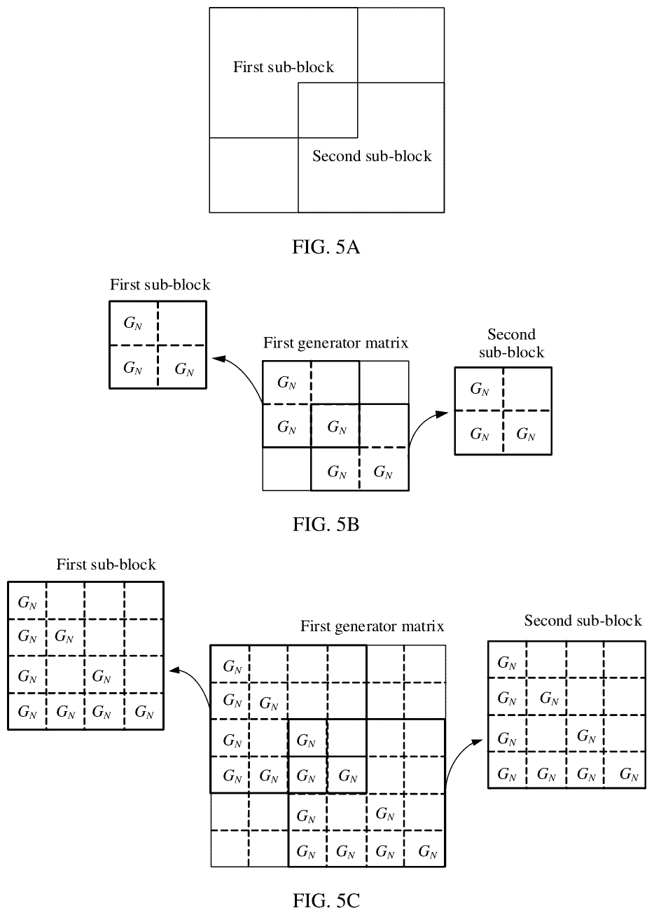

The following describes a first generator matrix with reference to FIG. 5A to FIG. 5C.

FIG. 5A is a schematic diagram of a first generator matrix according to this embodiment of this application. FIG. 5B is a schematic diagram of another first generator matrix according to this embodiment of this application. FIG. 5C is a schematic diagram of still another first generator matrix according to this embodiment of this application.

Refer to FIG. 5A. The first generator matrix includes two sub-blocks, which are denoted as a first sub-block and a second sub-block. The first sub-block is the same as the second sub-block. The first sub-block is located on the top-left portion of the first generator matrix, and the second sub-block is located on the bottom-right portion of the first generator matrix. The bottom-right corner area of the first sub-block overlaps the top-left corner area of the second sub-block, and distribution of elements in the bottom-right corner area of the first sub-block is the same as distribution of elements in the top-left corner area of the second sub-block.

Refer to FIG. 5B. The first generator matrix includes a first sub-block and a second sub-block, and each of the first sub-block and the second sub-block is

$$[ \begin{matrix}{G}_{N} & {0}_{N} \\ {G}_{N} & {G}_{N}\end{matrix} ] .$$

In this case, the first generator matrix may be

$$[ \begin{matrix}{G}_{N} & {0}_{N} & {0}_{N} \\ {G}_{N} & {G}_{N} & {0}_{N} \\ {0}_{N} & {G}_{N} & {G}_{N}\end{matrix} ] .$$

The first sub-block is located on the top-left portion of the first generator matrix, and the second sub-block is located on the bottom-right portion of the first generator matrix. A first sub-matrix in the first sub-block overlaps a second sub-matrix in the second sub-block. Coordinates of the first sub-matrix in the first sub-block are (2, 2), and coordinates of the second sub-matrix in the second sub-block are (1, 1).

Refer to FIG. 5C. The first generator matrix includes a first sub-block and a second sub-block, and each of the first sub-block and the second sub-block is

$$[ \begin{matrix}{G}_{N} & {0}_{N} & {0}_{N} & {0}_{N} \\ {G}_{N} & {G}_{N} & {0}_{N} & {0}_{N} \\ {G}_{N} & {0}_{N} & {G}_{N} & {0}_{N} \\ {G}_{N} & {G}_{N} & {G}_{N} & {G}_{N}\end{matrix} ] .$$

In this case, the first generator matrix may be

$$[ \begin{matrix}{G}_{N} & {0}_{N} & {0}_{N} & {0}_{N} & {0}_{N} & {0}_{N} \\ {G}_{N} & {G}_{N} & {0}_{N} & {0}_{N} & {0}_{N} & {0}_{N} \\ {G}_{N} & {0}_{N} & {G}_{N} & {0}_{N} & {0}_{N} & {0}_{N} \\ {G}_{N} & {G}_{N} & {G}_{N} & {G}_{N} & {0}_{N} & {0}_{N} \\ {0}_{N} & {0}_{N} & {G}_{N} & {0}_{N} & {G}_{N} & {0}_{N} \\ {0}_{N} & {0}_{N} & {G}_{N} & {G}_{N} & {G}_{N} & {G}_{N}\end{matrix} ] .$$

The first sub-block is located on the top-left portion of the first generator matrix, and the second sub-block is located on the bottom-right portion of the first generator matrix. Four first sub-matrices in the first sub-block overlap four second sub-matrices in the second sub-block. Coordinates of the four first sub-matrices in the first sub-block are (3, 3), (3, 4), (4, 3), and (4, 4); and coordinates of the four second sub-matrices in the second sub-block are (1, 1), (1, 2), (2, 1), and (2, 2).

It should be noted that, for ease of description and viewing, in FIG. 5B and FIG. 5C, marks of 0_{N} are omitted in the figures, that is, all blank sub-matrices in FIG. 5B to FIG. 5C are 0_{N}.

S303: Generate a second generator matrix based on the first generator matrix.

The second generator matrix includes T sub-blocks, and a position relationship between two adjacent sub-blocks of the T sub-blocks is determined based on the preset position relationship, where T is a positive integer. Optionally, the position relationship between two adjacent sub-blocks of the T sub-blocks is the same as the preset position relationship.

The quantity T of sub-blocks included in the second generator matrix may be determined based on the first generator matrix, a size of the sub-block, and an encoding length N′, and the second generator matrix is generated based on the first generator matrix and the quantity T.

Optionally, T is a minimum integer that enables a first condition to be satisfied, and the first condition is that a size of the second generator matrix is greater than or equal to the encoding length. The second generator matrix is a square matrix, and the size of the second generator matrix may be expressed by a quantity of rows or columns included in the second generator matrix, that is, the size of the second generator matrix is the quantity of rows or columns included in the second generator matrix.

For example, T satisfies the following relationship:

$$v + ( T - 2 ) * u < {N}^{′} \leq v + ( T - 1 ) * u ,$$

v is the size of the sub-block (the sub-block is a square matrix, and v represents a quantity of rows or columns of elements included in the sub-block), N′ is the encoding length, N′ is an integer greater than 1, and u is a distance between two adjacent sub-blocks. The distance between two adjacent sub-blocks may be expressed by a distance (a difference between row numbers or a difference between column numbers) between first elements (for example, the first element may be an element with coordinates (1, 1) in the sub-block) in the two adjacent sub-blocks.

For example, if the size v of the sub-block is 512, the encoding length N′ is 2048, and the distance u between two adjacent sub-blocks is 256, T is 7.

For example, if the size v of the sub-block is 512, the encoding length N′ is 1500, and the distance u between two adjacent sub-blocks is 256, T is 5.

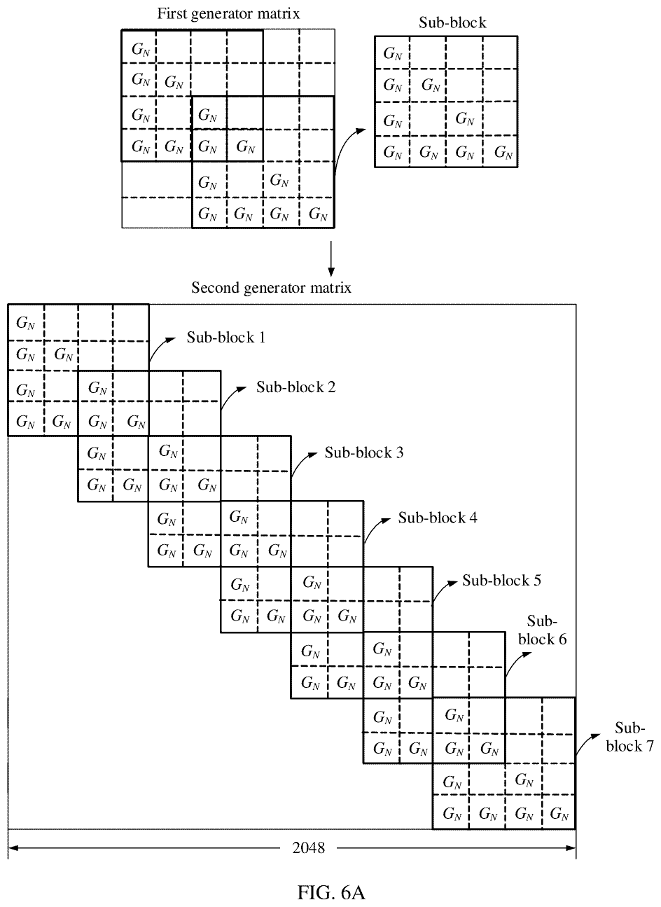

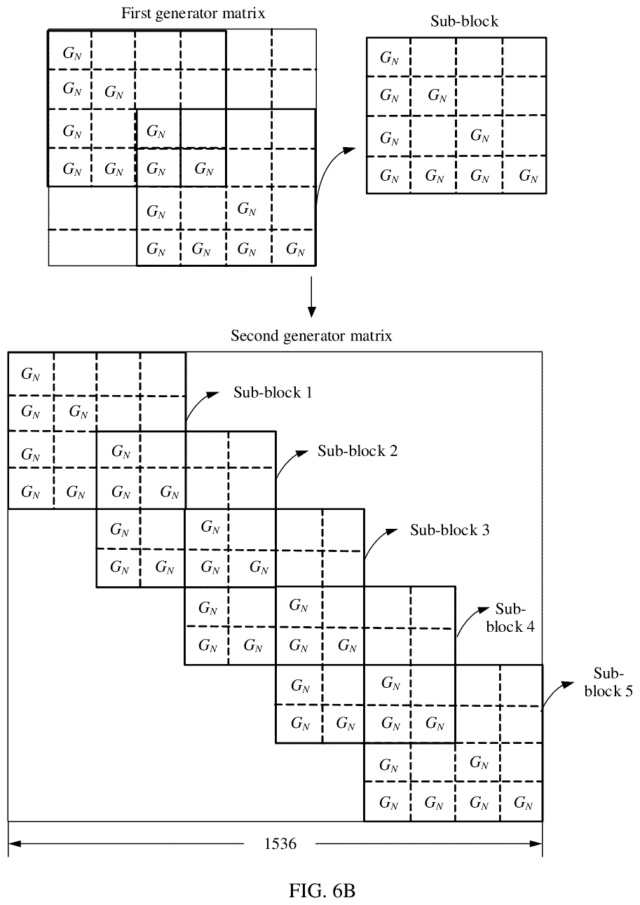

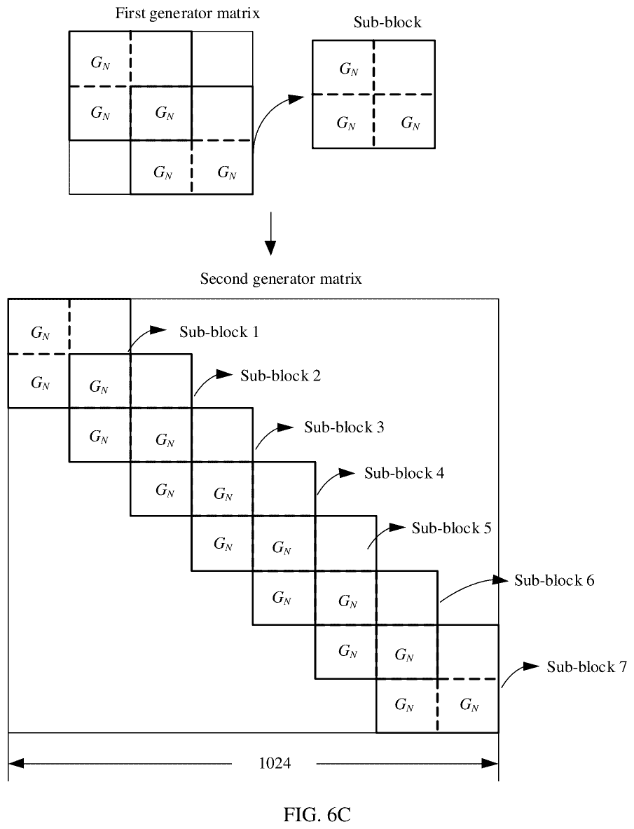

The following describes, with reference to FIG. 6A to FIG. 6C, the second generator matrix by using specific examples.

FIG. 6A is a schematic diagram of a second generator matrix according to this embodiment of this application. Refer to FIG. 6A, the first generator matrix includes two sub-blocks, each sub-block includes 16 sub-matrices, a part of sub-matrices are G_{N}, and a part of sub-matrices are 0_{N}. FIG. 6A shows a position relationship between two sub-blocks.

If a size of each sub-matrix is 128 (including 128 rows and 128 columns), a size of the sub-block is 512, a distance between the two sub-blocks in the first generator matrix is 256. If the encoding length N′ is 2048, the second generator matrix includes seven sub-blocks denoted as a sub-block 1, a sub-block 2, . . . , a sub-block 6, and a sub-block 7. A position relationship between every two adjacent sub-blocks in the seven sub-blocks is the same as a position relationship between the two sub-blocks in the first generator matrix. A size (a quantity of rows or columns included in the second generator matrix) of the second generator matrix is 2048.

FIG. 6B is a schematic diagram of another second generator matrix according to this embodiment of this application. Refer to FIG. 6B. It is assumed that the first generator matrix includes two sub-blocks, each sub-block includes 16 sub-matrices, a part of sub-matrices are G_{N}, and a part of sub-matrices are 0_{N}. FIG. 6B shows a position relationship between the two sub-blocks.

If a size of each sub-matrix is 128 (including 128 rows and 128 columns), a size of the sub-block is 512, and a distance between the two sub-blocks in the first generator matrix is 256. If the encoding length N′ is 1500, the second generator matrix includes five sub-blocks denoted as a sub-block 1, a sub-block 2, a sub-block 3, a sub-block 4, and a sub-block 5, and a position relationship between every two adjacent sub-blocks in the five sub-blocks is the same as a position relationship between the two sub-blocks in the first generator matrix. A size (a quantity of rows or columns included in the second generator matrix) of the second generator matrix is 1536.

FIG. 6C is a schematic diagram of still another second generator matrix according to this embodiment of this application. Refer to FIG. 6C. It is assumed that the first generator matrix includes two sub-blocks, each sub-block includes four sub-matrices, a part of sub-matrices are G_{N}, and a part of sub-matrices are 0_{N}. FIG. 6C shows a position relationship between the two sub-blocks.

If a size of each sub-matrix is 128 (including 128 rows and 128 columns), a size of the sub-block is 256, a distance between the two sub-blocks in the first generator matrix is 128. If the encoding length N′ is 1024, the second generator matrix includes seven sub-blocks denoted as a sub-block 1, a sub-block 2, . . . , a sub-block 6, and a sub-block 7. A position relationship between every two adjacent sub-blocks in the seven sub-blocks is the same as a position relationship between the two sub-blocks in the first generator matrix. A size (a quantity of rows or columns included in the second generator matrix) of the second generator matrix is 1024.

It should be noted that, in FIG. 6A to FIG. 6C, all sub-matrices except G_{N} are 0_{N}. For ease of description and viewing, marks of ON are omitted in the figures, that is, all blank sub-matrices in FIG. 6A to FIG. 6C are 0_{N}.

It should be noted that FIG. 6A to FIG. 6C show merely the examples of the second generator matrix, but do not limit the second generator matrix. Certainly, there may alternatively be another second generator matrix. This is not specifically limited in this embodiment of this application.

S304. Polar encode the K to-be-encoded bits based on the second generator matrix, to obtain encoded bits.

If the size of the second generator matrix is equal to the encoding length, the K to-be-encoded bits are polar encoded based on the second generator matrix, to obtain the encoded bits.

If the size of the second generator matrix is greater than the encoding length, a third generator matrix is first determined in the second generator matrix, and the K to-be-encoded bits are polar encoded based on the third generator matrix, to obtain the encoded bits. The third generator matrix is a matrix taken from the top-left corner area of the second generator matrix, or the third generator matrix is a matrix taken from the bottom-right corner area of the second generator matrix. The third generator matrix is a square matrix.

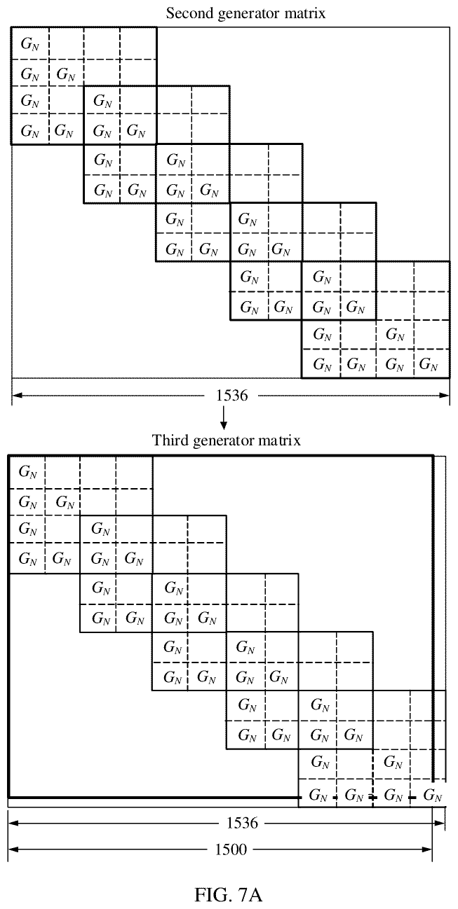

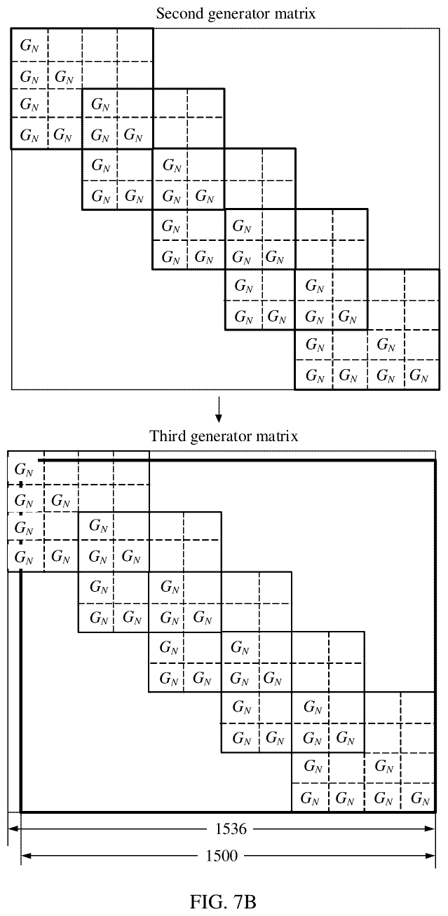

The following describes the third generator matrix with reference to FIG. 7A and FIG. 7B.

FIG. 7A is a schematic diagram of a third generator matrix according to this embodiment of this application. Refer to FIG. 7A. If the encoding length is 1500, and the size of the second generator matrix is 1536, a matrix with a size 1500 may be taken as the third generator matrix from the top-left corner area of the second generator matrix.

FIG. 7B is a schematic diagram of another third generator matrix according to this embodiment of this application. Refer to FIG. 7B. If the encoding length is 1500, and the size of the second generator matrix is 1536, a matrix with a size 1500 may be taken as the third generator matrix from the bottom-right corner area of the second generator matrix.

When the K to-be-encoded bits are polar encoded, K sub-channels with highest reliability may be determined from a plurality of sub-channels corresponding to the K to-be-encoded bits; positions of the K to-be-encoded bits may be determined based on the K sub-channels with the highest reliability; a to-be-encoded sequence may be determined based on the positions of the K to-be-encoded bits, where the to-be-encoded sequence includes the K to-be-encoded bits and frozen bits; and the to-be-encoded sequence may be polar encoded based on the second generator matrix to obtain encoded bits.

Optionally, the positions of the K to-be-encoded bits are positions corresponding to the K sub-channels with the highest reliability. After the positions of the K to-be-encoded bits are determined, information bits (the to-be-encoded bits) are filled in the positions of the K to-be-encoded bits, and the frozen bits are filled in other positions, to obtain an encoded sequence. The encoded sequence includes N′ bits, the N′ bits include K information bits and N′−K frozen bits.

For example, if the encoding length is 8, a quantity of to-be-encoded bits is 4, and sub-channels with highest reliability in the eight sub-channels are a sub-channel 4, a sub-channel 6, a sub-channel 7, and a sub-channel 8, positions corresponding to the sub-channel 4, the sub-channel 6, the sub-channel 7, and the sub-channel 8 are used to carry information bits, and other sub-channels are used to carry frozen bits. In this case, the to-be-encoded sequence may be 00010111, where 1 represents an information bit, and 0 represents a frozen bit.

The K sub-channels with the highest reliability may be determined in the following manner:

### First Manner:

P groups of sub-channels are determined from the plurality of sub-channels, where P is a positive integer. Xᵢ first sub-channels are determined from an i^{th} group of sub-channels based on reliability of the i^{th} group of sub-channels, where the K sub-channels with the highest reliability include first sub-channels determined in each group of sub-channels, Xᵢ first sub-channels are Xᵢ sub-channels with highest reliability in the i^{th} group of sub-channels, i is an integer, 1≤i≤P, Xᵢ is a positive integer, and Σᵢ₌₁^{i=P} Xᵢ=K.

Optionally, a quantity of sub-channels included in a group of sub-channels may be the same as a size of a sub-matrix. For example, if a size of a sub-matrix is 16, a group of sub-channels includes 16 sub-channels.

Optionally, a quantity of sub-channels included in a group of sub-channels may be the same as a size of a sub-block. For example, if a size of a sub-block is 64, a group of sub-channels includes 64 sub-channels.

Reliability of each group of sub-channels may be calculated in advance and stored. The reliability of each group of sub-channels may be stored in the following two manners:

Manner 1: A ranking sequence of the stored reliability may satisfy r={r₁, r₂, . . . , r_{N}}, where rᵢ represents a sub-channel sequence number of a group of sub-channels, a position of rᵢ in the r sequence represents reliability rankings of the sub-channel rᵢ in all sub-channels, and a higher ranking indicates higher reliability.

For example, if a group of sub-channels includes eight sub-channels, sequence numbers of the eight sub-channels are 1, 2, . . . , 7, and 8, and a reliability ranking sequence is r={4, 5, 3, 6, 7, 2, 1, 8}, it indicates that reliability of the eight sub-channels satisfies: the sub-channel 4>the sub-channel 5>the sub-channel 3>the sub-channel 6>the sub-channel 7>the sub-channel 2>the sub-channel 1>the sub-channel 8.

Manner 2: A ranking sequence of the stored reliability satisfies w={w₁, w₂, . . . , w_{N}}, where wᵢ represents a value of reliability of an i^{th} sub-channel in a group of sub-channels; larger wᵢ indicates higher reliability of the i^{th} sub-channel; and if wᵢ>wⱼ, it indicates that the reliability of the i^{th} sub-channel is greater than reliability of a j^{th} sub-channel.

For example, if a group of sub-channels includes eight sub-channels, and a ranking sequence of reliability satisfies w={2.1, 3, 4.5, 5, 3.2, 2, 2.6, 7}, it indicates that reliability of the eight sub-channels is separately shown in Table 1:

TABLE 1

| Sub-channel | Reliability |
|---|---|
| Sub-channel 1 | 2.1 |
| Sub-channel 2 | 3 |
| Sub-channel 3 | 4.5 |
| Sub-channel 4 | 5 |
| Sub-channel 5 | 3.2 |
| Sub-channel 6 | 2 |
| Sub-channel 7 | 2.6 |
| Sub-channel 8 | 7 |

Optionally, rankings of reliability of sub-channels in different groups may be the same or may be different. When the rankings of the reliability of the sub-channels in the different groups are the same, reliability of only one group of sub-channels may be stored.

### Second Manner:

Reliability of all sub-channels corresponding to the encoding length is calculated, the sub-channels are sorted in descending order of the reliability of all the sub-channels, and first K sub-channels of the sorted sub-channels are determined as the K sub-channels with the highest reliability.

Optionally, the reliability of all the sub-channels corresponding to the encoding length may be calculated in advance, and a sequence of the reliability is stored. If a maximum encoding length supported by a protocol is N*T, T reliability sequences may be calculated in advance and stored, where N is a size of a sub-matrix, and lengths of the T reliability sequences are T, 2T, 3T, . . . , and N*T.

In an actual application process, if the encoding length N′ satisfies the following condition: t′−1<N′<t′, a prestored reliability sequence with a length t′*N may be selected, and the K sub-channels with the highest reliability may be determined from the reliability sequence with the length of t′*N.

Calculation of the reliability of the sub-channels shown in this embodiment of this application includes intra-short-code reliability calculation and inter-short-code reliability calculation. Calculation of the reliability within the short code is the same as an existing calculation manner.

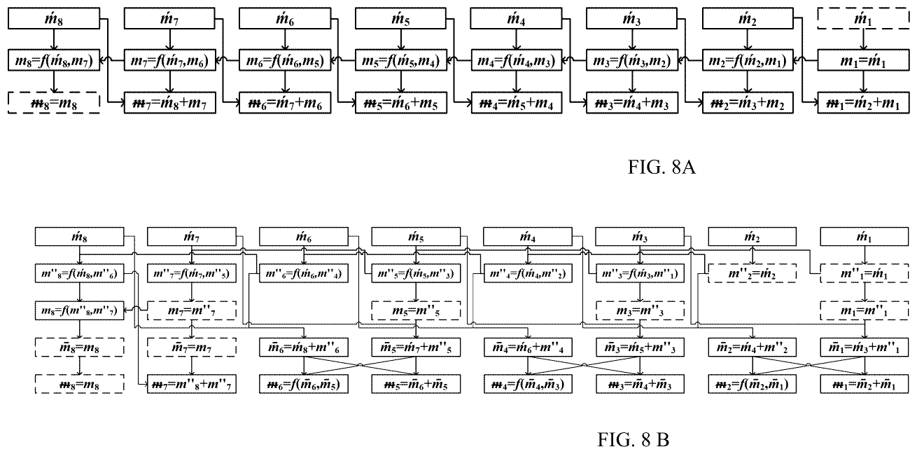

Optionally, when second generator matrices are different, manners of calculating sub-channel reliability are also different. The following describes, with reference to FIG. 8A to FIG. 8B, a manner of calculating sub-channel reliability by using a specific example.

Example 1: It is assumed that the second generator matrix is the second generator matrix shown in FIG. 6C, and encoding corresponding to the second generator matrix may also be referred to as two-coupling encoding.

The following describes, with reference to 8A, a sub-channel reliability determining process.

FIG. 8A is a schematic diagram of a decoding process according to an embodiment of this application. Refer to FIG. 8A. \acute{m}_{ι} is input first reliability of an i^{th} group of sub-channels, and [symbol] ᵢ is calculated third reliability of the i^{th} group of sub-channels, where i is an integer between 1 and 8. An f operation is f(m₁, m₂)=φ⁻¹(1−(1−ϕ(m₁))(1−ϕ(m₂))), where

$$ϕ ( x ) = \{ \begin{matrix}1 - \frac{1}{\sqrt{4 π x}} {\int }_{- ∞}^{∞} tanh \frac{u}{2} {e}^{- \frac{{( u - x )}^{2}}{4 x}} du , & x > 0 , \\ 1 , & x = 0.\end{matrix} ,$$

and ϕ⁻¹(x) is an inverse function of ϕ(x).

Refer to FIG. 8A. It is first determined that second reliability m₁ of a first group of sub-channels is first reliability \acute{m}₁ of the first group of sub-channels; then, an f operation is performed on m₁ and \acute{m}₂, to obtain second reliability m₂ of a second group of sub-channels; then, an f operation is performed on m₂ and \acute{m}₃ to obtain second reliability m₃ of a third group of sub-channels; this method is applied by analogy until second reliability of eight groups of sub-channels is obtained. This is expressed by using formulas: m₁=\acute{m}₁, m₂=f(\acute{m}₂, m₁), m₃=f(\acute{m}₃, m₂), m₄=f(\acute{m}₄, m₃), m₅=f(\acute{m}₅, m₄), m₆=f(\acute{m}′₆, m₅), m₇=f(\acute{m}₇, m₆), and m₈=f(\acute{m}₈, m₇).

Refer to FIG. 8A. It is first determined that third reliability [symbol] ₈ of an eighth group of sub-channels is second reliability m₈ of the eighth group of sub-channels; then, it is determined that third reliability [symbol] ₇ of a seventh group of sub-channels is a sum of \acute{m}₈ and m₇; then, it is determined that third reliability [symbol] ₆ of a sixth group of sub-channels is a sum of \acute{m}₇ and m₆; this method is applied by analogy until third reliability of the first group of sub-channels is obtained. This is expressed by using formulas: [symbol] ₈=m₈, [symbol] ₇=\acute{m}₈+m₇, [symbol] ₆=\acute{m}₇+m₆, [symbol] ₅=\acute{m}₆+m₅, [symbol] ₄=\acute{m}₅+m₄, [symbol] ₃=\acute{m}₄+m₃, [symbol] ₂=\acute{m}₃+m₂, and [symbol] ₁=\acute{m}₂+m₁.

FIG. 8B is a schematic diagram of another decoding process according to an embodiment of this application. Refer to FIG. 8B. \acute{m}_{ι} is input first reliability of an i^{th} group of sub-channels, and an f operation is the same as the f operation shown in FIG. 8A.

First, mᵢ″ is calculated based on \acute{m}_{ι}, where m₁″=\acute{m}₁, m₂″=\acute{m}₂, m₃″=f(\acute{m}₃, m₁″), m₄″=f(\acute{m}₄, m₂″), m₅″=f(\acute{m}₅, m₃″), m₆″=f(\acute{m}₆, m₄″), m₇″=f(\acute{m}₇, m₅″), and m₈″=f(\acute{m}₈,m₆″).

Then, mᵢ is calculated based on mᵢ′, where m₁=m₁″, m₃=m₃″, m₅=m₅″, m₇=m₇″, and m₈=f(m₈″, m₇″).

Then, m̅ᵢ is calculated based on the foregoing calculated parameters, where m̅₁=\acute{m}₃+m₁″, m̅₂=\acute{m}₄+m₂″, m̅₃=\acute{m}₅+m₃″, m̅₄=\acute{m}₆+m₄″, \hat{m}₅=\hat{m}₇+m₅″, m̅₆=\acute{m}₈+m₆″, m̅₇=m₇, and m̅₈=m₈.

Then, final reliability [symbol] ᵢ of the sub-channels is calculated based on the foregoing calculated parameters, where [symbol] ₁=m̅₂+m̅₁, [symbol] ₂=f(m̅₂, m̅₁), [symbol] ₃=m̅₄+m̅₃, [symbol] ₄=f(m̅₄, m̅₃), [symbol] ₅=m̅₆+m̅₅, [symbol] ₆=f(m̅₆, m̅₅), [symbol] ₇=m̅₈+m̅₇, and [symbol] ₈=m₈.

The following describes an encoding method in this application with reference to a diagram of encoding.

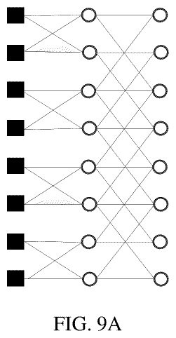

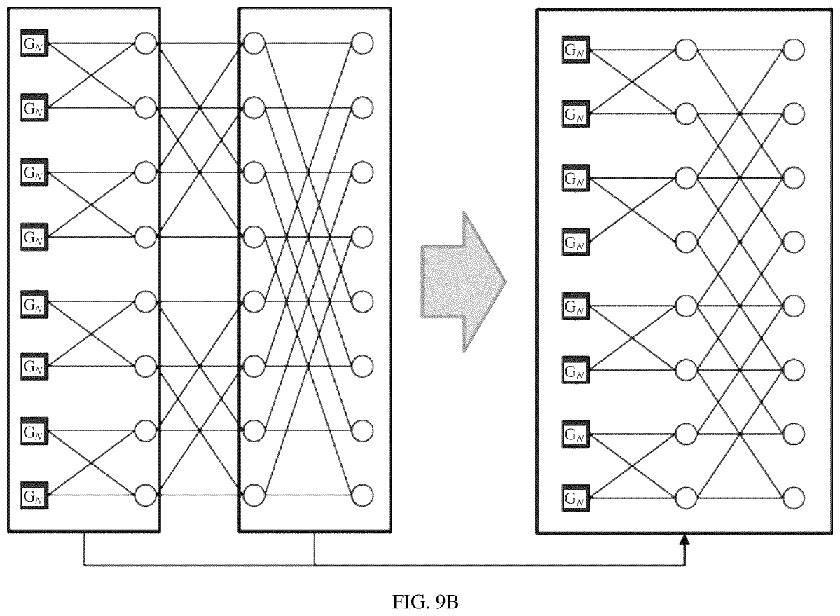

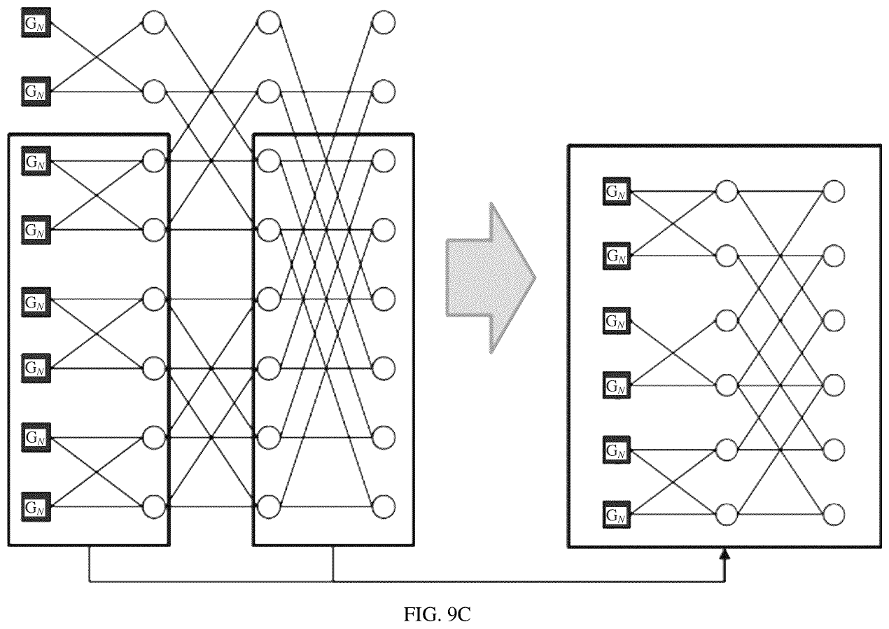

FIG. 9A is another diagram of encoding according to this embodiment of this application. A second generator matrix corresponding to the diagram of encoding is the second generator matrix in FIG. 6C.

Refer to FIG. 9A. In comparison with the diagram of encoding shown in FIG. 2, a leftmost block in FIG. 9A represents a diagram of encoding short codes, instead of representing one information bit or one frozen bit. For example, a code length of the short code may be a size N of a sub-matrix. A circle in each column except a first column represents one part and one bit vector, instead of representing one part and one bit.

In the foregoing diagram of encoding/decoding, a quantity of polarizations (a quantity of columns at stages in the diagram of encoding/decoding) of each short code with a length N is log₂(N). On this basis, the short code is further polarized twice, and a long code with a code length N′ may be obtained. Therefore, a quantity of polarizations of the long code with the code length N′ is log₂(N)+2, and further, total encoding/decoding complexity is N′*(log₂(N)+2). Because N may be set to a constant that does not vary with N′, when N′ is very large, the constant term may be ignored, and encoding/decoding complexity is O(N′).

A polar code shown in this application may be referred to as a coupling polar code. From a perspective of a diagram of encoding, a diagram of encoding the coupling polar code may be considered as recombination or clipping of the original diagram of encoding the long polar code. The following describes the diagram of encoding in detail with reference to FIG. 9B and FIG. 9C.

FIG. 9B is still another diagram of encoding according to this embodiment of this application. Refer to FIG. 9B. Several columns may be extracted from the original diagram of encoding the long polar code, and then combined to obtain a diagram of encoding a coupling polar code.

FIG. 9C is yet another diagram of encoding according to this embodiment of this application. Refer to FIG. 9C. Several rows and several columns may be extracted from the original diagram of encoding the long polar code, and then combined to obtain a diagram of encoding a coupling polar code.

After obtaining the encoded bits, a transmit end sends the encoded bits. After being rate matched, interleaved, and modulated, the encoded bits are transmitted to a receive end through a channel.

According to the encoding method provided in this embodiment of this application, when the K to-be-encoded bits need to be encoded, the first generator matrix is first determined, then the second generator matrix is generated based on the first generator matrix, and the K to-be-encoded bits are polar encoded based on the second generator matrix. The first generator matrix includes the at least two sub-blocks distributed based on the preset position relationship, each sub-block includes a plurality of first generator matrix cores, the second generator matrix includes the T sub-blocks, and the position relationship between two adjacent sub-blocks of the T sub-blocks is determined based on the preset position relationship. Therefore, it may be learned that the second generator matrix includes a plurality of sub-blocks arranged according to the foregoing preset position relationship, and each sub-block includes a plurality of first generator matrix cores. Therefore, polar encoding the K to-be-encoded bits based on the second generator matrix is equivalent to: polar encoding a plurality of short codes, and coupling the plurality of short codes to obtain an encoding result. This can reduce encoding complexity.

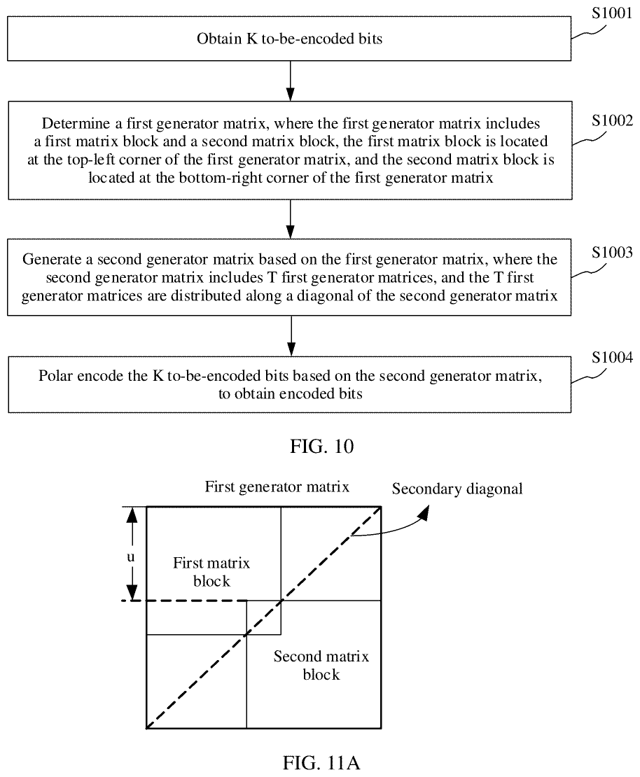

The following describes another encoding method with reference to FIG. 10.

FIG. 10 is a schematic flowchart of another encoding method according to an embodiment of this application. Refer to FIG. 10. The method may include the following steps.

S1001: Obtain K to-be-encoded bits.

K is a positive integer.

It should be noted that, for a process of performing step S1001, refer to step S301.

Details are not described herein again.

S1002: Determine a first generator matrix.

It should be noted that the first generator matrix in the embodiment in FIG. 10 is equivalent to the sub-block in the embodiment in FIG. 3, and description of the sub-block in the embodiment in FIG. 3 is applicable to the first generator matrix in the embodiment in FIG. 10. Details are not described herein again.

The first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance (which may also be a distance between the first matrix block and the second matrix block for short below) between a first element in the first matrix block and a second element in the second matrix block is u in a diagonal direction of the first generator matrix, where u is an integer greater than or equal to 1.

Optionally, the first element may be an element at the top-left corner of the first matrix block, and the second element may be an element at the top-left corner of the second generator matrix. The distance between the first element and the second element is a difference between row numbers of the first element and the second element or a difference between column numbers of the first element and the second element. For example, the first element is 0 or 1.

All elements in the first generator matrix except the first matrix block and the second matrix block may be elements 0.

Optionally, the first matrix block and the second matrix block may include one or more sub-matrices, and the sub-matrix may be G_{N} or 0_{N}. Each of the first matrix block and the second matrix block is a square matrix. For description of G_{N} and 0_{N}, refer to the embodiment shown in FIG. 3.

The first generator matrix satisfies self-similarity (or referred to as shift self-similarity). The self-similarity means that after the first matrix block in the first generator matrix moves (for example, moves along a main diagonal of the first generator matrix) by a preset distance, the first matrix block may move to a position of the second matrix block, and content in the first matrix block is the same as that in the second matrix block. When the first generator matrix has the self-similarity, elements in the first generator matrix satisfy a_{i,j}=a_{i+u,j+u}, where i is an integer, j is an integer, v is a size of the first generator matrix, u is an integer, 1≤i<v, 1≤j<v, 1<i+u≤v, and 1<j+u≤v.

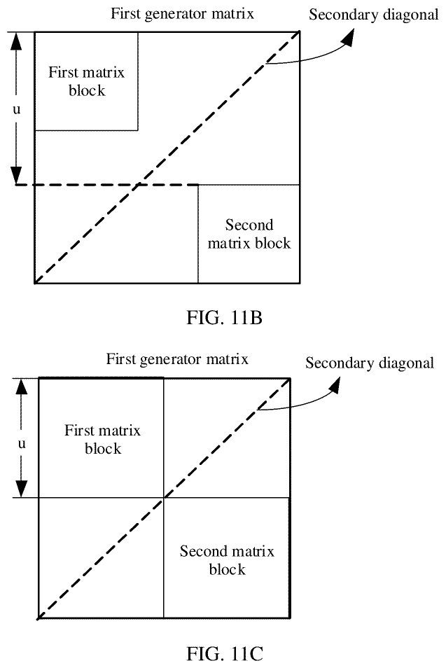

The following describes, with reference to FIG. 11A to FIG. 11C, that the first generator matrix includes a first matrix block and a second matrix block.

FIG. 11A is a schematic diagram of yet another first generator matrix according to this embodiment of this application. Refer to FIG. 11A. The first generator matrix includes a first matrix block and a second matrix block, the first matrix block is located at the top-left corner (or referred to as the top-left corner area) of the first generator matrix, and the second matrix block is located at the bottom-right corner (or referred to as the bottom-right corner area) of the first generator matrix. The first matrix block is the same as the second matrix block. The first generator matrix and a second generator matrix overlap each other.

FIG. 11B is a schematic diagram of still yet another first generator matrix according to this embodiment of this application. Refer to FIG. 11B. The first generator matrix includes a first matrix block and a second matrix block, the first matrix block is located at the top-left corner (or referred to as the top-left corner area) of the first generator matrix, and the second matrix block is located at the bottom-right corner (or referred to as the bottom-right corner area) of the first generator matrix. The first matrix block is the same as the second matrix block. There is a specific distance between the first generator matrix and a second generator matrix, that is, there is a specific distance between an element at the bottom-right corner of the first generator matrix (an element 1 for short) and an element at the top-left corner of the second generator matrix (an element 2 for short). For example, a difference between row numbers of element 2 and element 1 is greater than 1.

FIG. 11C is a schematic diagram of a further first generator matrix according to this embodiment of this application. Refer to FIG. 11C. The first generator matrix includes a first matrix block and a second matrix block, the first matrix block is located at the top-left corner (or referred to as the top-left corner area) of the first generator matrix, and the second matrix block is located at the bottom-right corner (or referred to as the bottom-right corner area) of the first generator matrix. The first matrix block is the same as the second matrix block. The first generator matrix is adjacent to a second generator matrix, that is, an element at the bottom-right corner of the first generator matrix (an element 1 for short) is adjacent to an element at the top-left corner of the second generator matrix (an element 2 for short). For example, a row number of the element 2 is greater than that of the element 1 by 1, and a column number of the element 2 is greater than that of element 1 by 1.

Optionally, elements in the first generator matrix are symmetrical along a secondary diagonal of the first generator matrix.

The following shows the first generator matrix by using specific examples.

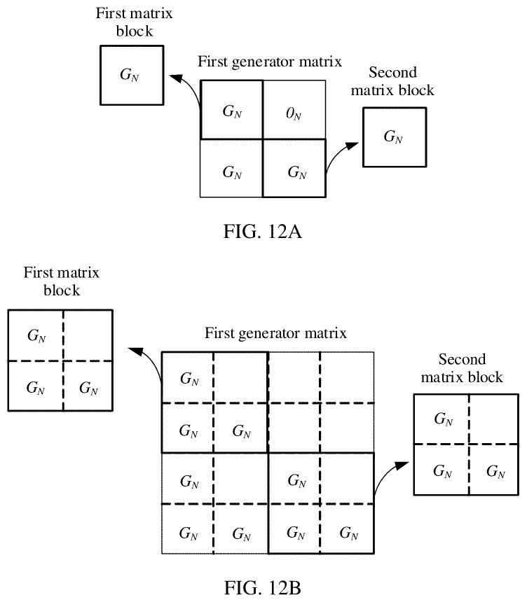

FIG. 12A is a schematic diagram of a still further first generator matrix according to this embodiment of this application. Refer to FIG. 12A. The first generator matrix includes a first matrix block and a second matrix block, and each of the first matrix block and the second matrix block includes one G_{N}. If N is 128, a distance between the first matrix block and the second matrix block is 128.

FIG. 12B is a schematic diagram of a yet further first generator matrix according to this embodiment of this application. Refer to FIG. 12B, the first generator matrix includes a first matrix block and a second matrix block, and each of the first matrix block and the second matrix block includes four sub-matrices. If N is 128, a distance between the first matrix block and the second matrix block is 256.

It should be noted that, for ease of description and viewing, in FIG. 12A and FIG. 12B, marks of 0_{N} omitted in the figures, that is, all blank sub-matrices in FIG. 12A and FIG. 12B are 0_{N}. FIG. 12A and FIG. 12B show merely examples of the first generator matrix, and do not limit the first generator matrix.

S1003: Determine the second generator matrix based on an encoding length and the first generator matrix.

The second generator matrix includes T first generator matrices, the T first generator matrices are distributed along a diagonal (the diagonal may be a main diagonal) of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

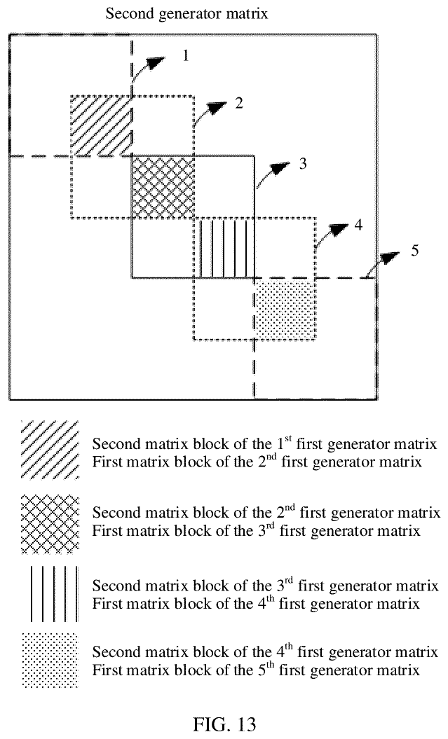

The following describes the second generator matrix with reference to FIG. 13.

FIG. 13 is a schematic diagram of yet another second generator matrix according to this embodiment of this application. Refer to FIG. 13. The second generator matrix includes five first generator matrices. The five first generator matrices are distributed along a main diagonal of the second generator matrix, reference numerals of the first generator matrices increase successively in a downward and rightward extension direction of the main diagonal of the second generator matrix, and a matrix at the top-left corner of the second generator matrix is the 1^{st} first generator matrix. For example, refer to FIG. 13. A first generator matrix indicated by a reference numeral 1 is the 1^{st} first generator matrix, a first generator matrix indicated by a reference numeral 2 is the 2^{nd} first generator matrix, and this method is applied by analogy. A first generator matrix indicated by a reference numeral 5 is the 5^{th} first generator matrix.

Refer to FIG. 13. A second matrix block of the 1^{st} first generator matrix overlaps a first matrix block of the 2^{nd} first generator matrix. A second matrix block of the 2^{nd} first generator matrix overlaps a first matrix block of the 3^{rd} first generator matrix. A second matrix block of the 3^{rd} first generator matrix overlaps a first matrix block of the 4^{th} first generator matrix. A second matrix block of the 4^{th} first generator matrix overlaps a first matrix block of the 5^{th} first generator matrix.

T is a minimum integer that enables a first condition to be satisfied, and the first condition is that a size of the second generator matrix is greater than or equal to the encoding length.

For example, T satisfies the following relationship:

$$v + ( T - 2 ) * u < {N}^{′} \leq v + ( T - 1 ) * u ,$$

v is a size of the first generator matrix, N′ is the encoding length, and N′ is an integer greater than 1.

For example, if the size v of the first generator matrix is 512, the encoding length N′ is 2048, and the distance u between two adjacent sub-blocks is 256, T is 7.

For example, if the size v of the first generator matrix is 512, the encoding length N′ is 1500, and the distance u between two adjacent sub-blocks is 256, T is 5.

Optionally, the quantity T of first generator matrices included in the second generator matrix may be determined based on the encoding length and the first generator matrix, and then the second generator matrix is generated based on the first generator matrix and the quantity T. For example, the first generator matrix may be copied and moved T−1 times in a direction of the main diagonal of the first generator matrix, to obtain the second generator matrix. A distance for moving once is u, and the moving distance is a quantity of moved rows or columns. For example, if three rows are moved by, the moving distance is 3.

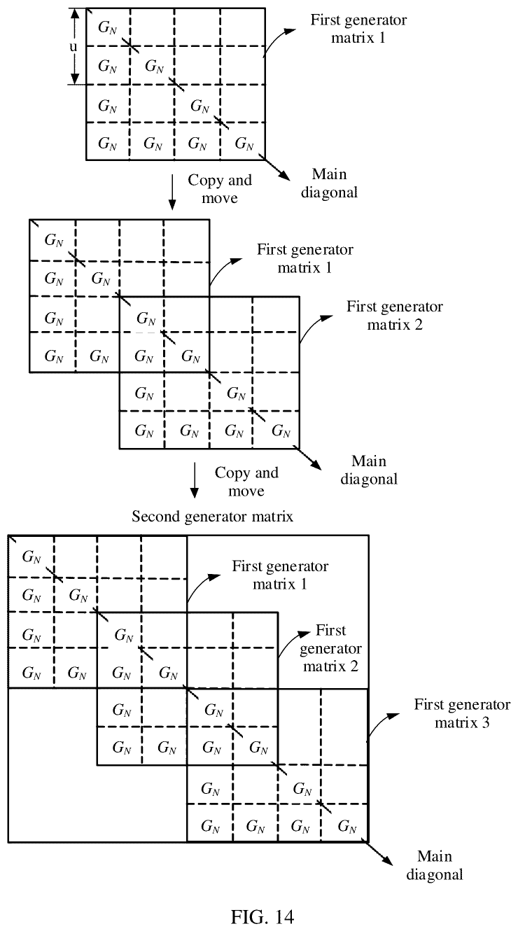

The following describes, with reference to FIG. 14, a process of generating the second generator matrix based on the first generator matrix.

FIG. 14 is a schematic diagram of a process of generating the second generator matrix according to this embodiment of this application. Refer to FIG. 14. The first generator matrix includes 16 sub-matrices, a part of sub-matrices are G_{N}, and a part of sub-matrices are 0_{N}. The first generator matrix satisfies the self-similarity, and a distance (a row spacing or a column spacing) between the first matrix block and the second matrix block in the first generator matrix is u. If it is determined that the second generator matrix includes three first generator matrices, a first generator matrix needs to be copied and moved twice.

Refer to FIG. 14. In a process of copying and moving for the first time, a first generator matrix 1 is copied, and the copied first generator matrix 1 is moved in a direction of a main diagonal by u rows (a diagonal distance corresponding to the u rows is \sqrt{2}*u), to obtain a first generator matrix 2. A first matrix block of the first generator matrix 2 overlaps a second matrix block of the first generator matrix 1.

Refer to FIG. 14. In a process of copying and moving for the second time, the first generator matrix 2 is copied, and the copied first generator matrix 2 is moved by u rows in the direction of the main diagonal (a diagonal distance corresponding to the u rows is \sqrt{2}*u), to obtain s first generator matrix 3. A first matrix block of the first generator matrix 3 overlaps a second matrix block of the first generator matrix 2.

It is determined that the second generator matrix includes the first generator matrix 1, the first generator matrix 2, and the first generator matrix 3.

It should be noted that FIG. 14 shows merely an example manner of generating the second generator matrix based on the first generator matrix, and does not limit the manner. In FIG. 14, all sub-matrices except G_{N} are 0_{N}. For ease of description and viewing, marks of 0_{N} omitted in the figure, that is, all blank sub-matrices in FIG. 14 are 0_{N}.

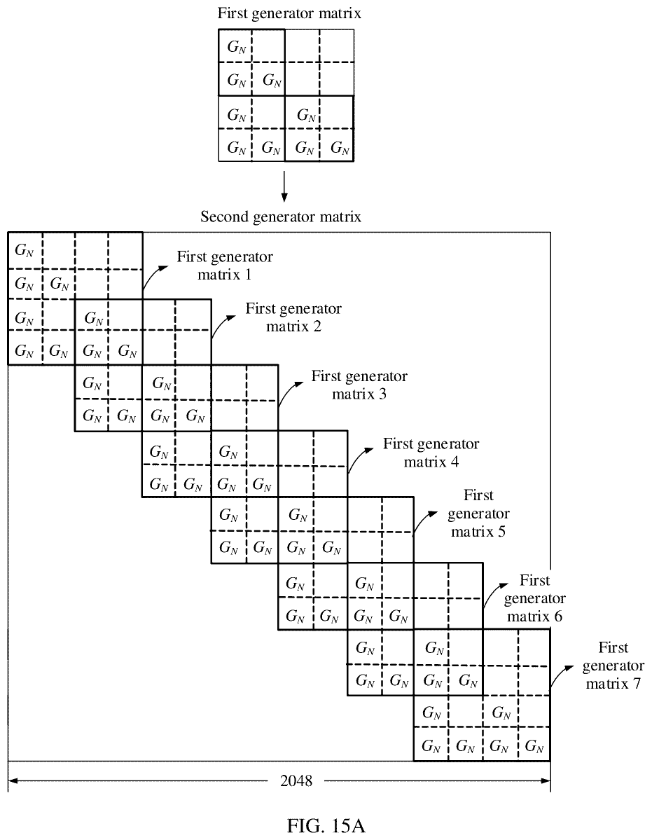

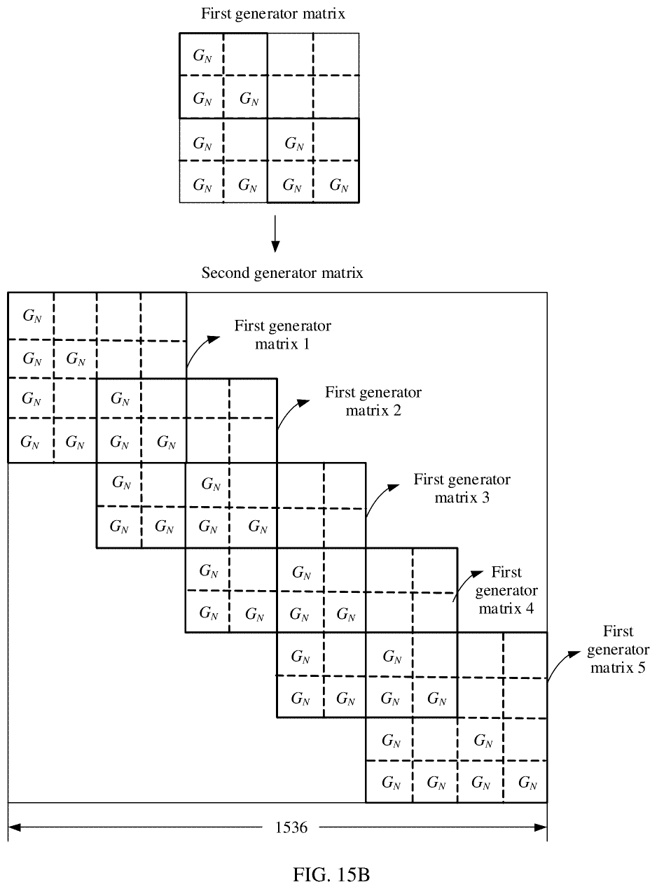

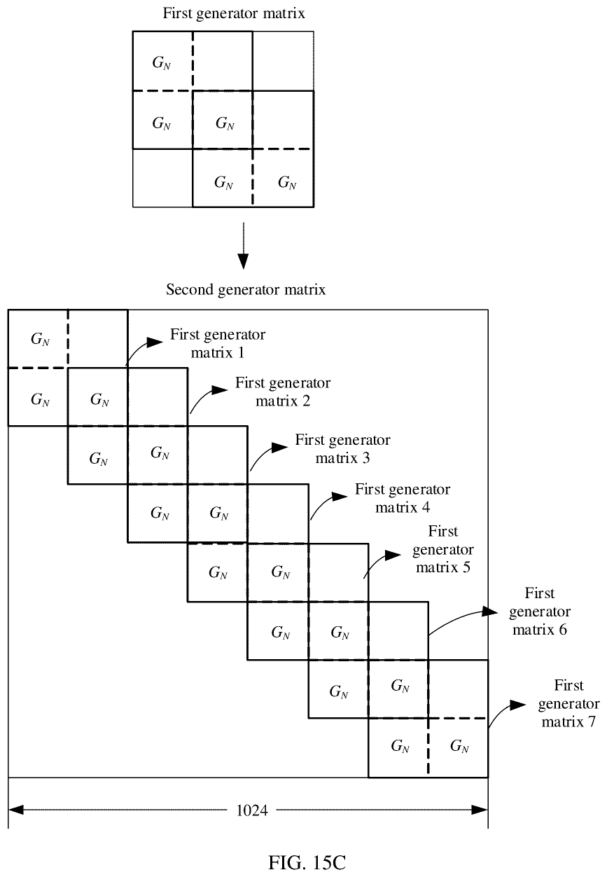

The following describes, with reference to FIG. 15A to FIG. 15C, the second generator matrix by using specific examples.

FIG. 15A is a schematic diagram of still yet another second generator matrix according to this embodiment of this application. Refer to FIG. 15A. The first generator matrix includes 16 sub-matrices, a part of sub-matrices are G_{N}, and a part of sub-matrices are 0_{N}. The first generator matrix satisfies the self-similarity.

If a size of each sub-matrix is 128 (including 128 rows and 128 columns), a size of a sub-block is 512, a distance between two sub-blocks in the first generator matrix is 256. If the encoding length N′ is 2048, the second generator matrix includes seven first generator matrices, a first matrix block of a latter first generator matrix in every two adjacent generator matrices of the seven first generator matrices overlaps a second matrix block of a former first generator matrix, and a size (a quantity of rows or columns included in the second generator matrix) of the second generator matrix is 2048.

FIG. 15B is a schematic diagram of a further second generator matrix according to this embodiment of this application. Refer to FIG. 15B. The first generator matrix includes 16 sub-matrices, a part of sub-matrices are G_{N}, and a part of sub-matrices are 0_{N}. The first generator matrix satisfies the self-similarity.

If a size of each sub-matrix is 128 (including 128 rows and 128 columns), a size of a sub-block is 512, a distance between two sub-blocks in the first generator matrix is 256. If the encoding length N′ is 1500, the second generator matrix includes five first generator matrices, a first matrix block of a latter first generator matrix in every two adjacent generator matrices of the five first generator matrices overlaps a second matrix block of a former first generator matrix, and a size (a quantity of rows or columns included in the second generator matrix) of the second generator matrix is 1536.

FIG. 15C is a schematic diagram of a still further second generator matrix according to this embodiment of this application. Refer to FIG. 15C. The first generator matrix includes 16 sub-matrices, a part of sub-matrices are G_{N}, and a part of sub-matrices are 0_{N}. The first generator matrix satisfies the self-similarity.

If a size of each sub-matrix is 128 (including 128 rows and 128 columns), a size of a sub-block is 256, a distance between two sub-blocks in the first generator matrix is 128. If the encoding length N′ is 1024, the second generator matrix includes seven first generator matrices, a first matrix block of a latter first generator matrix in every two adjacent generator matrices of the seven first generator matrices overlaps a second matrix block of a former first generator matrix, and a size (a quantity of rows or columns included in the second generator matrix) of the second generator matrix is 1024.

It should be noted that, in FIG. 15A to FIG. 15C, all sub-matrices except G_{N} are 0_{N}. For ease of description and viewing, marks of 0_{N} omitted in the figures, that is, all blank sub-matrices in FIG. 15A to FIG. 15C are 0_{N}.

S1004: Polar encode the K to-be-encoded bits based on the second generator matrix, to obtain encoded bits.

It should be noted that, for a process of performing step S1004, refer to step S304. Details are not described herein again.

According to the encoding method provided in this embodiment of this application, when the K to-be-encoded bits need to be encoded, the first generator matrix is first determined, then the second generator matrix is generated based on the first generator matrix, and the K to-be-encoded bits are polar encoded based on the second generator matrix. Because the first generator matrix has the self-similarity, and the second generator matrix includes a plurality of first matrix blocks, polar encoding the K to-be-encoded bits based on the second generator matrix is equivalent to: polar encoding a plurality of short codes, and coupling the plurality of short codes, to obtain an encoding result. This can reduce encoding complexity.

Based on any one of the foregoing encoding methods, the following describes a decoding method based on the foregoing encoding method.

FIG. 16 is a schematic diagram of decoding according to an embodiment of this application. Refer to FIG. 16. The method may include the following steps.

S1601: Receive polar encoded bit information.

The bit information includes N′ first log-likelihood ratio (likelihood rate, LLR) sequences, where N′ is a positive integer. For example, after receiving a signal, a receive end performs processing such as demodulation on the signal to obtain N′ first LLRs, and performs polar decoding based on the received N′ first LLRs. Regardless of whether a transmit end sends a bit 1 or a bit 0, the receive end may make an incorrect determining. Given a signal r, a likelihood ratio is a ratio of a probability p(r|b=0) of correctly determining 0 by the receive end to a probability p(r|b=1)] of correctly determining 1 by the receive end. To facilitate calculation processing, the likelihood ratio is a natural logarithm. In this case, a log-likelihood ratio, that is, LLR=ln [p(r|b=0)/p(r|b=1)], may be obtained. The LLR may be a floating-point number.

S1602: Polar decode the bit information based on a second generator matrix, to obtain polar decoded bits.

Optionally, the second generator matrix is the polar encoded matrix in the embodiment in FIG. 3. For related description of the second generator matrix, refer to the embodiment shown in FIG. 3. Details are not described herein again.

Optionally, the second generator matrix is the polar encoded matrix in the embodiment in FIG. 10. For related description of the second generator matrix, refer to the embodiment shown in FIG. 10. Details are not described herein again.

In the embodiment shown in FIG. 3 or FIG. 10, the encoded sequence includes the N′ unencoded bits, and the N′ unencoded bits include the K information bits and the N′−K frozen bits. N′ bits may include T groups of unencoded bits, and each group of unencoded bits includes N unencoded bits, that is, N′=N*T.

N′ first LLRs include T first LLR sequences. In other words, N′ first LLRs may be divided into T first LLR sequences, and one of the first LLR sequences includes N LLRs.

One of the first LLR sequences may be related to two or more groups of unencoded bits. For example, if the encoded sequence includes eight groups of unencoded bits, and FIG. 6C shows the second generator matrix, N′ first LLRs include eight first LLR sequences, and Table 2 shows a relationship between the eight first LLR sequences and a group of unencoded bits.

TABLE 2

| Identifier of a | |
|---|---|
| first LLR sequence | Group of unencoded bits |
| First LLR sequence 1 | First group of unencoded bits and |
| | second group of unencoded bits |
| First LLR sequence 2 | Second group of unencoded bits |
| | and third group of unencoded bits |
| First LLR sequence 3 | Third group of unencoded bits |
| | and fourth group of unencoded bits |
| First LLR sequence 4 | Fourth group of unencoded bits |
| | and fifth group of unencoded bits |
| First LLR sequence 5 | Fifth group of unencoded bits |
| | and sixth group of unencoded bits |
| First LLR sequence 6 | Sixth group of unencoded bits |
| | and seventh group of unencoded bits |
| First LLR sequence 7 | Seventh group of unencoded bits |
| | and eighth group of unencoded bits |
| First LLR sequence 8 | Eighth group of unencoded bits |

Refer to Table 2. The first LLR sequence 1 is related to the first group of unencoded bits and the second group of unencoded bits, the first LLR sequence 2 is related to the second group of unencoded bits and the third group of unencoded bits, and this method is applied by analogy.

To perform accurate decoding, the first LLR sequence may be decoupled to obtain a second LLR sequence corresponding to each first LLR sequence, so that one second LLR sequence corresponds to one group of unencoded bits. For example, the first LLR sequences shown in Table 2 are decoupled to obtain eight second LLR sequences. Table 3 shows a relationship between the eight second LLR sequences and the groups of unencoded bits.

TABLE 3

| Identifier of a first LLR sequence | Group of unencoded bits |
|---|---|
| First LLR sequence 1 | First group of unencoded bits |
| First LLR sequence 2 | Second group of unencoded bits |
| First LLR sequence 3 | Third group of unencoded bits |
| First LLR sequence 4 | Fourth group of unencoded bits |
| First LLR sequence 5 | Fifth group of unencoded bits |
| First LLR sequence 6 | Sixth group of unencoded bits |
| First LLR sequence 7 | Seventh group of unencoded bits |
| First LLR sequence 8 | Eighth group of unencoded bits |

Refer to Table 2. The first LLR sequence 1 is related to the first group of unencoded bits, the first LLR sequence 2 is related to the second group of unencoded bits, and this method is applied by analogy.

Optionally, a second LLR sequence may be determined based on a first LLR sequence in the following manner: determining an i^{th} second LLR sequence based on an i^{th} first LLR sequence and at least one of first (i−1) second LLR sequences, where i is an integer between 2 and T.

Optionally, polar decoding may be performed based on the T second LLR sequences in the following manner: determining to obtain a T^{th} decoding result based on a T^{th} second LLR sequence; and determining an i^{th} decoding result based on the i^{th} second LLR sequence and at least one of an (i+1)^{th} decoding result to the T^{th} decoding result, where i is an integer between 1 and T−1.

The following describes, by using specific examples, a process of determining the second LLR sequence and performing polar decoding based on the T second LLR sequences.

Example 1: It is assumed that the second generator matrix is the second generator matrix shown in FIG. 6C, and encoding corresponding to the second generator matrix may also be referred to as two-coupling encoding.

The i^{th} second LLR sequence may be determined in the following manner: determining the i^{th} second LLR sequence based on the i^{th} first LLR sequence and an (i−1)^{th} second LLR sequence, wherein a 1^{st} second LLR sequence is the same as the 1^{st} first LLR sequence.

The i^{th} decoding result may be determined in the following manner: determining the i^{th} decoding result based on the (i+1)^{th} decoding result, an (i+1)^{th} first LLR sequence, and an i^{th} second LLR sequence.

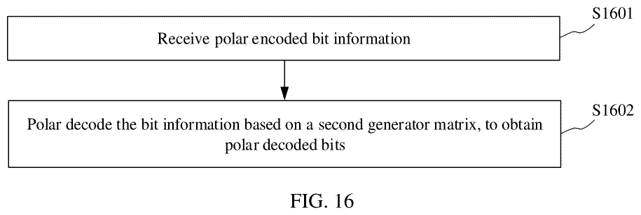

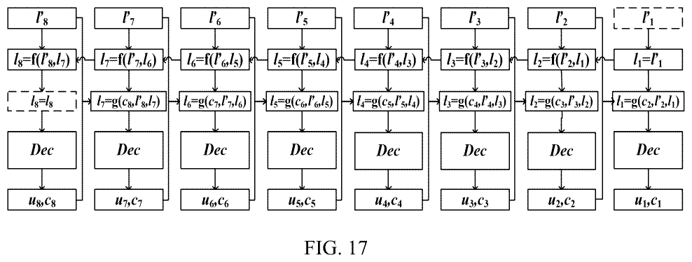

The following describes, with reference to FIG. 17, a decoding process corresponding to the foregoing second generator matrix.

FIG. 17 is a schematic diagram of a decoding process according to this embodiment of this application. Refer to FIG. 17, lᵢ′ is an i^{th} first LLR sequence, lᵢ is an i^{th} second LLR sequence, uᵢ is an unencoded i^{th} bit sequence, and cᵢ is an encoded i^{th} bit sequence, where i is an integer between 1 and 8. An f operation is: f(L₁, L₂)=sgn(L₁) sgn(L₂) min(|L₁|, |L₂|). A g operation is: g(u, L₁, L₂)=(−1)^{û}^{₁}^{^{2+i−1}}. L₁+L₂, and c is encoded to obtain u.

After receiving the N′ LLRs, the receive end divides the received N′ LLRs into eight first LLR sequences, where the eight first LLR sequences are denoted as l₁′, l₂′, l₃′, l₄′, l₅′, l₆′, l₇′, and l₈′. Second LLR sequences corresponding to the eight first LLR sequences are denoted as l₁, l₂, l₃, l₄, l₅, l₆, l₇, and l₈.

Refer to FIG. 17. The 1^{st} second LLR sequence 41 is first determined, an f operation is performed on the 1^{st} second LLR sequence l₁ and the 2^{nd} first LLR sequence l₂′ to obtain the 2^{nd} second LLR sequence l₂, an f operation is performed on the 2^{nd} second LLR sequence l₂ and the 3^{rd} first LLR sequence l₃′ to obtain the 3^{rd} second LLR sequence l₃, and this method is applied by analogy until the eight second LLR sequences are obtained. This is expressed by using formulas: l₁=l₁′, l₂=f(l₂′, l₁), l₃=f(l₃′, l₂), l₄=f(l₄′, l₃), l₅=f(l₅′, l₄), l₆=f(l₆′, l₅), l₇=f(l₇′, l₆), and l₈=f(l₈′, l₇).

Refer to FIG. 17, the 8^{th} second LLR sequence l₈ is first input into a decoder for decoding, to obtain an 8^{th} decoding result u₈, where u₈ includes N decoded bits. u₈ is encoded to obtain an 8^{th} encoded bit sequence c₈. A g operation is performed on c₈, l₈′, and l₇ to obtain a g operation result [symbol] ₈, and the g operation result [symbol] ₈ is input into the decoder for decoding, to obtain a 7^{th} decoding result u₇. u₇ is encoded to obtain a 7^{th} encoded bit sequence c₇. A g operation is performed on c₇, l₇′, and l₆ to obtain a g operation result [symbol] ₇, and the g operation result [symbol] ₇ is input into the decoder for decoding, to obtain a 6^{th} decoding result u₆. This method is applied by analogy until a 1^{st} decoding result u₁ is determined.

Example 2: It is assumed that the second generator matrix is the second generator matrix shown in FIG. 14, and encoding corresponding to the second generator matrix may also be referred to as four-coupling encoding.

The i^{th} second LLR sequence may be determined in the following manner: determining the i^{th} second LLR sequence based on the i^{th} first LLR sequence and an (i−2)^{th} second LLR sequence, where i is an integer between 3 and T. A 1^{st} second LLR sequence is the same as a 1^{st} first LLR sequence, and a 2^{nd} second LLR sequence is the same as a 2^{nd} first LLR sequence.

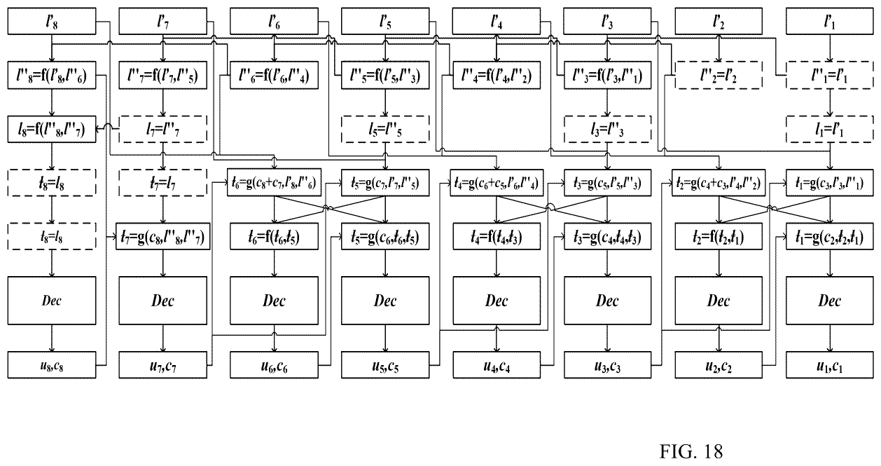

The following describes, with reference to FIG. 18, a decoding process corresponding to the foregoing second generator matrix.

FIG. 18 is a schematic diagram of another decoding process according to this embodiment of this application. An f operation in FIG. 18 may be the same as the g operation in FIG. 17.

Refer to FIG. 17. lᵢ′ is the i^{th} first LLR sequence. After receiving the N′ LLRs, the receive end divides the received N′ LLRs into eight first LLR sequences, where the eight first LLR sequences are denoted as l₁′, l₂′, l₃′, l₄′, l₅′, l₆′, l₇′, and l₈′.

First, lᵢ″ is calculated based on lᵢ′, where l₁″=l₁′, l₂′=l₂′, l₃″=f(l₂′, l₁″), l₄″=f(l₄′, l₂″), l₅″=f(l₅′, l₃″), l₆″=f(l₆′, l₄″), l₇″=f(l₇′, l₅″), and l₈″=f(l₈′, l₆″). lᵢ″ is the i^{th} second LLR sequence.

Then, lᵢ is calculated based on lᵢ″, where l₈=f(l₈″, l₇″), l₇=l₇″, l₅=l₅″, l₃=l₅″, and l₁=l₁′.

Then, decoding is performed based on the foregoing calculated parameters: l₈ is input into a decoder for decoding, to obtain an 8^{th} decoding result u₈, where u₈ includes N decoded bits. u₈ is encoded to obtain an 8^{th} encoded bit sequence c₈. A g operation is performed on c₈, l₈″, and l₇″, and a g operation result l₇ is input into the decoder for decoding, to obtain a 7^{th} decoding result u₇. u₇ is encoded to obtain a 7^{th} encoded bit sequence c₇. A g operation is performed on c₈+c₇, l₈′, and l₆″ to obtain a g operation result [symbol] ₆, and a g operation is performed on [symbol] ₆ and [symbol] ₅ to obtain a g operation result [symbol] ₆, where [symbol] ₅ is a result of a g operation on c₇, l₇′, and l₅″. [symbol] ₆ is input into the decoder for decoding, to obtain a 6^{th} decoding result u₆. This method is applied by analogy until a 1^{st} decoding result u₁ is determined.

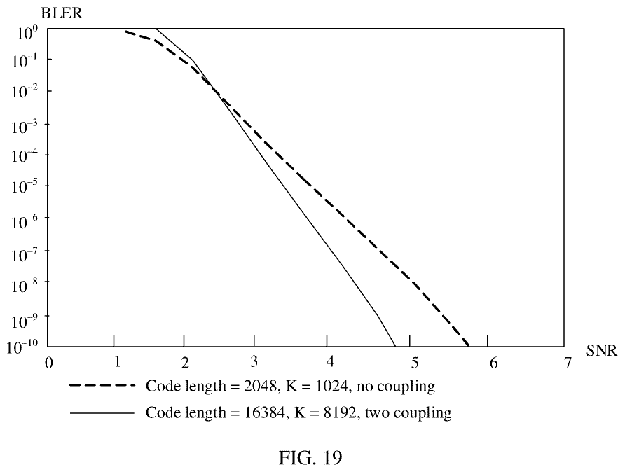

The following describes decoding performance of a decoding method in this application with reference to FIG. 19.

FIG. 19 is a schematic diagram of decoding performance according to an embodiment of this application. Refer to FIG. 19. A horizontal axis represents a signal-to-noise ratio (SNR), and a vertical axis represents a block error rate (BLER).

Refer to FIG. 19. When a code length is 2048, a quantity of information bits is 1024, and no coupling is performed (an existing manner), a dashed line shows a performance curve. When the code length is 16384, the quantity K of information bits is 8129, and a two-coupling operation is performed (for example, FIG. 6C shows the second generator matrix), a solid line shows a performance curve. It can be learned from FIG. 19 that a performance gain may be about 1 dB in the manner shown in this application.

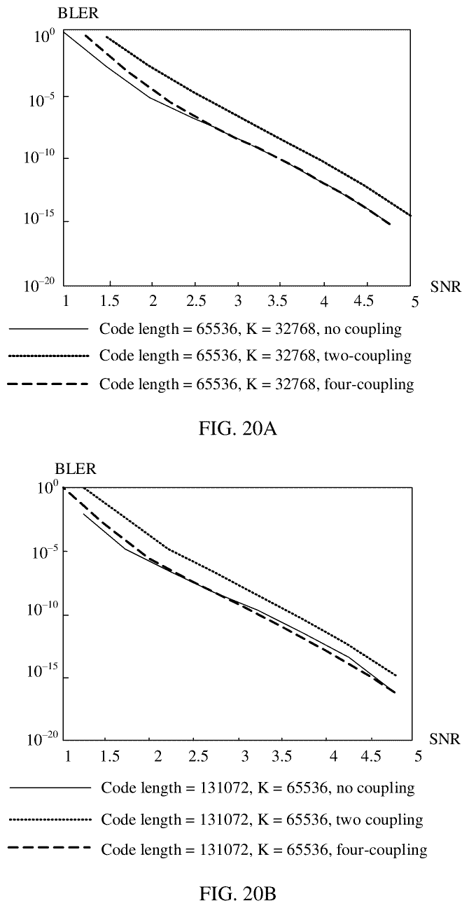

In an actual application process, compared with a long polar code, a coupling polar code has less complexity without a performance loss. When the code length increases to a specific value, coupling in a larger range cannot bring a significant performance gain. The following provides description with reference to FIG. 20A.

FIG. 20A is another schematic diagram of decoding performance according to this embodiment of this application. Refer to FIG. 20A. When the code length is 65536, the quantity K of information bits is 32768, and no coupling is performed (an existing manner), a solid line shows a performance curve. When the code length is 65536, the quantity K of information bits is 32768, and a two-coupling operation is performed (for example, FIG. 6C shows the second generator matrix), a dashed line shows a performance curve. When the code length is 65536, the quantity K of information bits is 32768, and a four-coupling operation is performed (for example, FIG. 14 shows the second generator matrix), another dashed line shows a performance curve.

FIG. 20B is still another schematic diagram of decoding performance according to this embodiment of this application. Refer to FIG. 20B. When the code length is 131072, the quantity K of information bits is 65536, and no coupling is performed (an existing manner), a solid line shows a performance curve. When the code length is 131072, the quantity K of information bits is 65536, and a two-coupling operation is performed (for example, FIG. 6C shows the second generator matrix), a dashed line shows a performance curve. When the code length is 131072, the quantity K of information bits is 65536, and a four-coupling operation is performed (for example, FIG. 14 shows the second generator matrix), another dashed line shows a performance curve.

When a coupling range is larger, encoding/decoding complexity is higher. In addition, it can be learned, from FIG. 20A and FIG. 20B, that a coupling range or width may be limited to some extent, or an appropriate coupling degree may be selected, so that software and hardware implementation complexity can be reduced as much as possible without a performance loss.

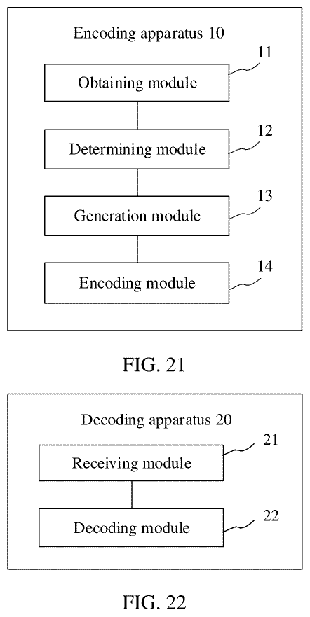

FIG. 21 is a schematic diagram of a structure of an encoding apparatus according to an embodiment of this application. Refer to FIG. 21. The encoding apparatus 10 may include an obtaining module 11, a determining module 12, a generation module 13, and an encoding module 14.

The obtaining module 11 is configured to obtain K to-be-encoded bits, where K is a positive integer.

The determining module 12 is configured to determine a first generator matrix. The first generator matrix includes at least two sub-blocks distributed based on a preset position relationship, and the sub-block includes a plurality of first generator matrix cores.

The generation module 13 is configured to generate a second generator matrix based on the first generator matrix. The second generator matrix includes T sub-blocks, and a position relationship between two adjacent sub-blocks of the T sub-blocks is determined based on the preset position relationship, where T is a positive integer.

The encoding module 14 is configured to polar encode the K to-be-encoded bits based on the second generator matrix, to obtain encoded bits.

Optionally, the obtaining module 11 may perform step S301 in the embodiment in FIG. 3.

Optionally, the determining module 12 may perform step S302 in the embodiment in FIG. 3.

Optionally, the generation module 13 may perform step S303 in the embodiment in FIG. 3.

Optionally, the encoding module 14 may perform step S304 in the embodiment in FIG. 3.

It should be noted that the encoding apparatus shown in this embodiment of this application may implement the technical solutions shown in the foregoing method embodiments. Implementation principles and beneficial effects thereof are similar to those of the method embodiments. Details are not described herein again.

In a possible implementation, the position relationship between two adjacent sub-blocks of the T sub-blocks is the same as the preset position relationship.

In a possible implementation, an overlapping portion exists in the at least two sub-blocks.

In a possible implementation, a first diagonal of the sub-block comprises the first generator matrix cores.

In a possible implementation, the plurality of first generator matrix cores in the sub-block are distributed in a lower triangular form.

In a possible implementation, distribution of the first generator matrix cores in the sub-block is the same as distribution of first elements in a second generator matrix core, a quantity of elements included in the second generator matrix core is the same as a quantity of sub-matrices included in the sub-block, and a sub-matrix included in the sub-block is the first generator matrix core or a zero matrix.

In a possible implementation, the first generator matrix includes two sub-blocks.

In a possible implementation, the quantity of sub-matrices included in the sub-block is 2*2, and the sub-matrix included in the sub-block is the first generator matrix core or the zero matrix.

In a possible implementation, the first generator matrix includes a first sub-block and a second sub-block, and a first sub-matrix in the first sub-block overlaps a second sub-matrix in the second sub-block; and
coordinates of the first sub-matrix in the first sub-block are (2, 2), and coordinates of the second sub-matrix in the second sub-block are (1, 1).

In a possible implementation, the quantity of sub-matrices included in the sub-block is 4*4, and the sub-matrix included in the sub-block is the first generator matrix core or the zero matrix.

In a possible implementation, the first generator matrix includes a first sub-block and a second sub-block, and four first sub-matrices in the first sub-block overlap four second sub-matrices in the second sub-block.

Coordinates of the four first sub-matrices in the first sub-block are (3, 3), (3, 4), (4, 3), and (4, 4); and
coordinates of the four second sub-matrices in the second sub-block are (1, 1), (1, 2), (2, 1), and (2, 2).

In a possible implementation, the K to-be-encoded bits are information bits. The encoding module 14 is specifically configured to:
determine K sub-channels with highest reliability in a plurality of sub-channels corresponding to the K to-be-encoded bits;
determine positions of the K to-be-encoded bits based on the K sub-channels with the highest reliability;
determine a to-be-encoded sequence based on the positions of the K to-be-encoded bits, where the to-be-encoded sequence comprises the K to-be-encoded bits and frozen bits; and
polar encode the to-be-encoded sequence based on the second generator matrix, to obtain the encoded bits.

In a possible implementation, the plurality of sub-channels include P groups of sub-channels, where P is a positive integer. The encoding module 14 is specifically configured to:
determine Xᵢ first sub-channels from an i^{th} group of sub-channels based on reliability of the i^{th} group of sub-channels, where the Xᵢ first sub-channels are Xᵢ sub-channels with highest reliability in the i^{th} group of sub-channels, i is an integer, 1≤i≤P, Xᵢ is a positive integer, and Σᵢ₌₁^{i=P} Xᵢ=K.

The K sub-channels with the highest reliability include the first sub-channels.

It should be noted that the encoding apparatus shown in this embodiment of this application may implement the technical solutions shown in the foregoing method embodiments. Implementation principles and beneficial effects thereof are similar to those of the method embodiments. Details are not described herein again.

FIG. 22 is a schematic diagram of a structure of a decoding apparatus according to an embodiment of this application. Refer to FIG. 22. The decoding apparatus 20 may include a receiving module 21 and a decoding module 22.

The receiving module 21 is configured to receive polar encoded bit information.

The decoding module 22 is configured to polar decode the bit information based on a second generator matrix, to obtain polar decoded bits.

The second generator matrix is generated based on a first generator matrix, the first generator matrix includes at least two sub-blocks distributed based on a preset position relationship, the sub-block includes a plurality of first generator matrix cores, the second generator matrix includes T sub-blocks, and a position relationship between two adjacent sub-blocks of the T sub-blocks is determined based on the preset position relationship, where T is a positive integer.

Optionally, the receiving module 21 may perform step S1601 in the embodiment in FIG. 16.

Optionally, the decoding module 22 may perform step S1602 in the embodiment in FIG. 16.

It should be noted that the decoding apparatus shown in this embodiment of this application may implement the technical solutions shown in the foregoing method embodiments.

Implementation principles and beneficial effects thereof are similar to those of the method embodiments. Details are not described herein again.

In a possible implementation, the position relationship between two adjacent sub-blocks of the T sub-blocks is the same as the preset position relationship.

In a possible implementation, an overlapping portion exists in the at least two sub-blocks.

In a possible implementation, a first diagonal of the sub-block includes the first generator matrix cores.

In a possible implementation, the plurality of first generator matrix cores in the sub-block are distributed in a lower triangular form.

In a possible implementation, distribution of the first generator matrix cores in the sub-block is the same as distribution of first elements in a second generator matrix core, a quantity of elements included in the second generator matrix core is the same as a quantity of elements included in the sub-block, and an element included in the sub-block is the first generator matrix core or a zero matrix.

In a possible implementation, the first generator matrix includes two sub-blocks.

In a possible implementation, the quantity of elements included in the sub-block is 2*2, and the element included in the sub-block is the first generator matrix core or the zero matrix.

In a possible implementation, the first generator matrix includes a first sub-block and a second sub-block, and a first element in the first sub-block overlaps a second element in the second sub-block; and
coordinates of the first element in the first sub-block are (2, 2), and coordinates of the second element in the second sub-block are (1, 1).

In a possible implementation, the quantity of elements included in the sub-block is 4*4, and the element included in the sub-block is the first generator matrix core or the zero matrix.

In a possible implementation, the first generator matrix includes a first sub-block and a second sub-block, and four first elements in the first sub-block overlap four second elements in the second sub-block.

Coordinates of the four first elements in the first sub-block are (3, 3), (3, 4), (4, 3), and (4, 4); and
coordinates of the four second elements in the second sub-block are (1, 1), (1, 2), (2, 1), and (2, 2).

In a possible implementation, the bit information includes N′ first log-likelihood ratio LLR sequences, where N′ is a positive integer.

In a possible implementation, the N′ first LLRs include T first LLR sequences, and the first LLR sequence includes at least two first LLRs. The decoding module 22 is specifically configured to:
determine T second LLR sequences corresponding to the T first LLR sequences, where one of the first LLR sequences corresponds to one or more groups of unencoded bits, and one of the second LLR sequences corresponds to one group of unencoded bits; and
perform polar decoding based on the T second LLR sequences.

In a possible implementation, the decoding module 22 is specifically configured to:
determine an i^{th} second LLR sequence based on an i^{th} first LLR sequence and at least one of first (i−1) second LLR sequences, where i is an integer between 2 and T.

In a possible implementation, a coupling degree of a code block is 2. The decoding module 22 is specifically configured to:
determine the i^{th} second LLR sequence based on the i^{th} first LLR sequence and an (i−1)^{th} second LLR sequence.

In a possible implementation, a 1^{st} second LLR sequence is the same as a 1^{st} first LLR sequence.

In a possible implementation, a coupling degree of a code block is 4. The decoding module 22 is specifically configured to:
determine the i^{th} second LLR sequence based on the i^{th} first LLR sequence and an (i−2)^{th} second LLR sequence, where i is an integer between 3 and T.

In a possible implementation, a 1^{st} second LLR sequence is the same as a 1^{st} first LLR sequence; and
a 2^{nd} second LLR sequence is the same as a 2^{nd} first LLR sequence.

In a possible implementation, the decoding module 22 is specifically configured to:
determine to obtain a T^{th} decoding result based on a T^{th} second LLR sequence; and determine an i^{th} decoding result based on the i^{th} second LLR sequence and at least one of an (i+1)^{th} decoding result to the T^{th} decoding result, where i is an integer between 1 and T−1.

In a possible implementation, a coupling degree of a code block is 2. The decoding module 22 is specifically configured to:
determine the i^{th} decoding result based on the (i+1)^{th} decoding result, an (i+1)^{th} first LLR sequence, and the i^{th} second LLR sequence.

It should be noted that the decoding apparatus shown in this embodiment of this application may implement the technical solutions shown in the foregoing method embodiments. Implementation principles and beneficial effects thereof are similar to those of the method embodiments. Details are not described herein again.

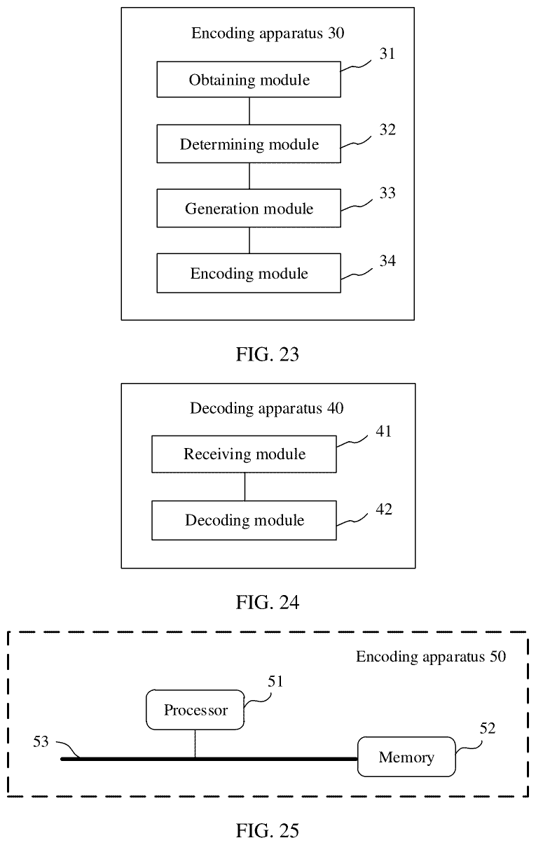

FIG. 23 is a schematic diagram of a structure of another encoding apparatus according to an embodiment of this application. Refer to FIG. 23. The encoding apparatus 30 may include an obtaining module 31, a determining module 32, a generation module 33, and an encoding module 34.

The obtaining module 31 is configured to obtain K to-be-encoded bits, where K is a positive integer.

The determining module 32 is configured to determine a first generator matrix. The first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1.

The generation module 33 is configured to generate a second generator matrix based on an encoding length and the first generator matrix. The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

The encoding module 34 is configured to polar encode the K to-be-encoded bits based on the second generator matrix, to obtain encoded bits.

Optionally, the obtaining module 31 may perform step S1001 in the embodiment in FIG. 10.

Optionally, the determining module 32 may perform step S1002 in the embodiment in FIG. 10.

Optionally, the generation module 33 may perform step S1003 in the embodiment in FIG. 10.

Optionally, the encoding module 34 may perform step S1004 in the embodiment in FIG. 10.

It should be noted that the encoding apparatus shown in this embodiment of this application may implement the technical solutions shown in the foregoing method embodiments. Implementation principles and beneficial effects thereof are similar to those of the method embodiments. Details are not described herein again.

In a possible implementation, no overlapping element exists in the first matrix block and the second matrix block.

In a possible implementation, a size of the first generator matrix is v*v, and an element in the first generator matrix satisfies a_{i,j}=a_{i+u,j+u}, where
i is an integer, j is an integer, v is a positive integer, u is an integer, 1≤i<v, 1≤j<v, 1<i+u≤v, and 1<j+u≤v.

In a possible implementation, elements in the first generator matrix are symmetrical along a secondary diagonal of the first generator matrix.

In a possible implementation, T is a minimum integer that enables a first condition to be satisfied, and the first condition is that a size of the second generator matrix is greater than or equal to the encoding length.

In a possible implementation, T satisfies the following relationship:

$$v + ( T - 1 ) * u < {N}^{′} \leq v + T * u ,$$

v is the size of the first generator matrix, N′ is the encoding length, and N′ is an integer greater than 1.

It should be noted that the encoding apparatus shown in this embodiment of this application may implement the technical solutions shown in the foregoing method embodiments. Implementation principles and beneficial effects thereof are similar to those of the method embodiments. Details are not described herein again.

FIG. 24 is a schematic diagram of a structure of another decoding apparatus according to an embodiment of this application. Refer to FIG. 24. The decoding apparatus 40 may include a receiving module 41 and a decoding module 42.

The receiving module 41 is configured to receive polar encoded bit information.

The decoding module 42 is configured to polar decode the bit information based on a second generator matrix, to obtain polar decoded bits. The second generator matrix is generated based on a first generator matrix.

The first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1.

The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

Optionally, the receiving module 41 may perform step S1601 in the embodiment in FIG. 16.

Optionally, the decoding module 42 may perform step S1602 in the embodiment in FIG. 16.

It should be noted that the decoding apparatus shown in this embodiment of this application may implement the technical solutions shown in the foregoing method embodiments. Implementation principles and beneficial effects thereof are similar to those of the method embodiments. Details are not described herein again.

In a possible implementation, no overlapping element exists in the first matrix block and the second matrix block.

In a possible implementation, a size of the first generator matrix is v*v, and an element in the first generator matrix satisfies a_{i,j}=a_{i+u,j+u}, where
i is an integer, j is an integer, v is a positive integer, u is an integer, 1≤i<v, 1≤j<v, 1<i+u≤v, and 1<j+u≤v.

In a possible implementation, elements in the first generator matrix are symmetrical along a secondary diagonal of the first generator matrix.

In a possible implementation, T is a minimum integer that enables a first condition to be satisfied, and the first condition is that a size of the second generator matrix is greater than or equal to the encoding length.

In a possible implementation, T satisfies the following relationship:

$$v + ( T - 1 ) * u < {N}^{′} \leq v + T * u ,$$

v is the size of the first generator matrix, N′ is the encoding length, and N′ is an integer greater than 1.

In a possible implementation, the bit information includes N′ first log-likelihood ratio LLR sequences, where N′ is a positive integer.

In a possible implementation, the N′ first LLRs include T first LLR sequences, and the first LLR sequence includes at least two first LLRs. The decoding module 42 is specifically configured to:
determine T second LLR sequences corresponding to the T first LLR sequences, where one of the first LLR sequences corresponds to one or more groups of unencoded bits, and one of the second LLR sequences corresponds to one group of unencoded bits; and
perform polar decoding based on the T second LLR sequences.

In a possible implementation, the decoding module 42 is specifically configured to:
determine an i^{th} second LLR sequence based on an i^{th} first LLR sequence and at least one of first (i−1) second LLR sequences, where i is an integer between 2 and T.

In a possible implementation, a coupling degree of a code block is 2. The decoding module 42 is specifically configured to:
determine the i^{th} second LLR sequence based on the i^{th} first LLR sequence and an (i−1)^{th} second LLR sequence.

In a possible implementation, a 1^{st} second LLR sequence is the same as a 1^{st} first LLR sequence.

In a possible implementation, a coupling degree of a code block is 4. The decoding module 42 is specifically configured to:
determine the i^{th} second LLR sequence based on the i^{th} first LLR sequence and an (i−2)^{th} second LLR sequence, where i is an integer between 3 and T.

In a possible implementation, a 1^{st} second LLR sequence is the same as a 1^{st} first LLR sequence; and
a 2^{nd} second LLR sequence is the same as a 2^{nd} first LLR sequence.

In a possible implementation, the decoding module 42 is specifically configured to:
determine to obtain a T^{th} decoding result based on a T^{th} second LLR sequence; and
determine an i^{th} decoding result based on the i^{th} second LLR sequence and at least one of an (i+1)^{th} decoding result to the T^{th} decoding result, where i is an integer between 1 and T−1.

In a possible implementation, a coupling degree of a code block is 2. The decoding module 42 is specifically configured to:
determine the i^{th} decoding result based on the (i+1)^{th} decoding result, an (i+1)^{th} first LLR sequence, and the i^{th} second LLR sequence.

It should be noted that the decoding apparatus shown in this embodiment of this application may implement the technical solutions shown in the foregoing method embodiments. Implementation principles and beneficial effects thereof are similar to those of the method embodiments. Details are not described herein again.

FIG. 25 is a schematic diagram of a hardware structure of still another encoding apparatus according to an embodiment of this application. Refer to FIG. 25. The encoding apparatus 50 may include a processor 51 and a memory 52.

The memory 52 is configured to store a computer program, and may be further configured to store intermediate data.

The processor 51 is configured to execute the computer program stored in the memory, to implement the steps in the foregoing encoding methods. For details, refer to related description in the foregoing method embodiments.

Optionally, the memory 52 may be independent, or may be integrated with the processor 51. In some implementations, the memory 52 may even be located outside the encoding apparatus 50.

When the memory 52 is a component independent of the processor 51, the encoding apparatus 50 may further include a bus 53 configured to connect the memory 52 and the processor 51.

Optionally, the encoding apparatus 50 may further include a transmitter. For example, the transmitter is configured to send encoded bits.

The encoding apparatus 50 provided in this embodiment may be a terminal device or a network device, and may be configured to perform the foregoing encoding methods. Implementations and technical effects thereof are similar to those of the encoding methods. Details are not described herein again in this embodiment.

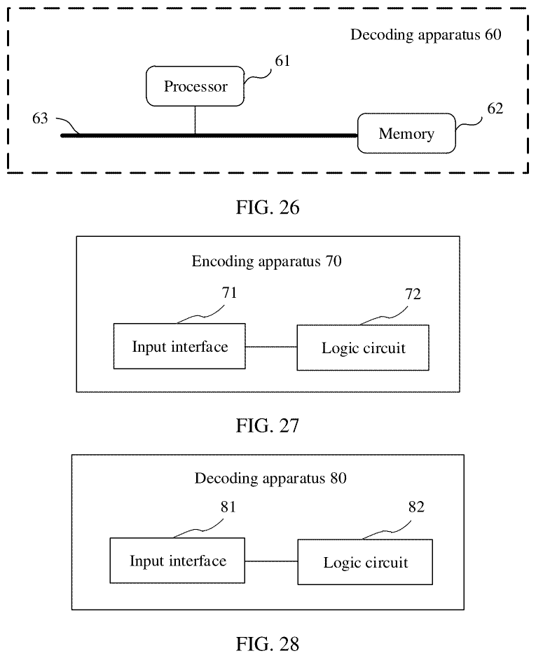

FIG. 26 is a schematic diagram of a hardware structure of still another decoding apparatus according to an embodiment of this application. Refer to FIG. 26. The decoding apparatus 60 may include a processor 61 and a memory 62.

The memory 62 is configured to store a computer program, and may be further configured to store intermediate data.

The processor 61 is configured to execute the computer program stored in the memory, to implement the steps in the foregoing decoding methods. For details, refer to related description in the foregoing method embodiments.

Optionally, the memory 62 may be independent, or may be integrated with the processor 61. In some implementations, the memory 62 may even be located outside the decoding apparatus 60.

When the memory 62 is a device independent of the processor 61, the decoding apparatus 60 may further include a bus 63 configured to connect the memory 62 and the processor 61.

Optionally, the decoding apparatus 60 may further include a receiver. For example, the receiver is configured to receive polar encoded bit information.

The decoding apparatus 60 provided in this embodiment may be a terminal device or a network device, and may be configured to perform the foregoing decoding methods. Implementations and technical effects thereof are similar to those of the decoding methods. Details are not described herein again in this embodiment.

FIG. 27 is a schematic diagram of a structure of yet another encoding apparatus according to an embodiment of this application. Refer to FIG. 27. The encoding apparatus 70 may include an input interface 71 and a logic circuit 72.

The input interface 71 is configured to obtain K to-be-encoded bits, where K is a positive integer.

The logic circuit 72 is configured to: determine a first generator matrix, where the first generator matrix includes at least two sub-blocks distributed based on a preset position relationship, and the sub-block includes a plurality of first generator matrix cores; generate a second generator matrix based on the first generator matrix, where the second generator matrix includes T sub-blocks, and a position relationship between two adjacent sub-blocks of the T sub-blocks is determined based on the preset position relationship, where T is a positive integer; and polar encode the K to-be-encoded bits based on the second generator matrix, to obtain encoded bits.

Optionally, the input interface 71 may have functions of the obtaining module 11 in the embodiment in FIG. 21. The logic circuit 72 may have functions of the determining module 11, the generation module 13, and the encoding module 14 in the embodiment in FIG. 21.

Optionally, the logic circuit 72 may have functions of the processor 61 in the embodiment in FIG. 25. The logic circuit 72 may further perform other steps in the encoding methods.

Optionally, the encoding apparatus 70 may further include an output interface. For example, the output interface may output encoded bits.

The encoding apparatus 70 provided in this embodiment of this application may implement the technical solutions shown in the foregoing method embodiments. Implementation principles and beneficial effects thereof are similar to the method embodiments. Details are not described herein again.

FIG. 28 is a schematic diagram of a structure of yet another decoding apparatus according to an embodiment of this application. Refer to FIG. 28. The decoding apparatus 80 may include an input interface 81 and a logic circuit 82.

The input interface 81 is configured to receive polar encoded bit information.

The logic circuit 82 is configured to polar decode the bit information based on a second generator matrix, to obtain polar decoded bits. The second generator matrix is generated based on a first generator matrix, the first generator matrix includes at least two sub-blocks distributed based on a preset position relationship, the sub-block includes a plurality of first generator matrix cores, the second generator matrix includes T sub-blocks, and a position relationship between two adjacent sub-blocks of the T sub-blocks is determined based on the preset position relationship, where T is a positive integer.

Optionally, the input interface 81 may have functions of the receiving module 21 in the embodiment in FIG. 22. The logic circuit 82 may have functions of the decoding module 22 in the embodiment in FIG. 22.

Optionally, the input interface 81 may have functions of the receiver in the embodiment in FIG. 26. The logic circuit 82 may have functions of the processor 61 in the embodiment in FIG. 26. The logic circuit 82 may further perform other steps in the decoding methods.

Optionally, the decoding apparatus 80 may further include an output interface. For example, the output interface may output a decoding result.

The decoding apparatus 80 provided in this embodiment of this application may implement the technical solutions shown in the foregoing method embodiments. Implementation principles and beneficial effects thereof are similar to the method embodiments. Details are not described herein again.

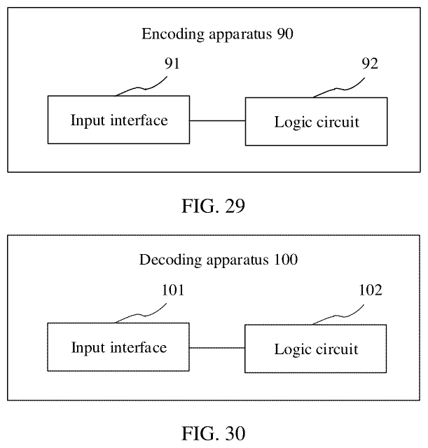

FIG. 29 is a schematic diagram of a structure of still yet another encoding apparatus according to an embodiment of this application. Refer to FIG. 29. The encoding apparatus 90 may include an input interface 91 and a logic circuit 92.

The input interface 91 is configured to obtain K to-be-encoded bits, where K is a positive integer.

The logic circuit 92 is configured to: determine a first generator matrix, where the first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1; determine a second generator matrix based on an encoding length and the first generator matrix, where the second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2; and polar encode the K to-be-encoded bits based on the second generator matrix, to obtain encoded bits.

Optionally, the input interface 91 may have functions of the obtaining module 31 in the embodiment in FIG. 23. The logic circuit 92 may have functions of the determining module 32, the generation module 33, and the encoding module 34 in the embodiment in FIG. 23.

Optionally, the logic circuit 92 may have functions of the processor 61 in the embodiment in FIG. 25. The logic circuit 92 may further perform other steps in the encoding methods.

Optionally, the encoding apparatus 90 may further include an output interface. For example, the output interface may output encoded bits.

The encoding apparatus 90 provided in this embodiment of this application may implement the technical solutions shown in the foregoing method embodiments. Implementation principles and beneficial effects thereof are similar to the method embodiments. Details are not described herein again.

FIG. 30 is a schematic diagram of a structure of still yet another decoding apparatus according to an embodiment of this application. Refer to FIG. 30. The decoding apparatus 100 may include an input interface 101 and a logic circuit 102.

The input interface 101 is configured to receive polar encoded bit information.

The logic circuit 102 is configured to polar decode the bit information based on a second generator matrix, to obtain polar decoded bits. The second generator matrix is generated based on a first generator matrix, the first generator matrix includes a first matrix block and a second matrix block, the first matrix block is located at the top-left corner of the first generator matrix, the second matrix block is located at the bottom-right corner of the first generator matrix, the first matrix block is the same as the second matrix block, and a distance between a first element in the first matrix block and a second element in the second matrix block is u in a diagonal direction of the first generator matrix, where u is an integer greater than or equal to 1. The second generator matrix includes T first generator matrices, the T first generator matrices are distributed along a diagonal of the second generator matrix, and a first matrix block of an (a+1)^{th} first generator matrix in the T first generator matrices overlaps a second matrix block of an a^{th} first generator matrix, where a is an integer greater than or equal to 1, and T is an integer greater than or equal to 2.

Optionally, the input interface 101 may have functions of the receiving module 41 in the embodiment in FIG. 24. The logic circuit 102 may have functions of the decoding module 42 in the embodiment in FIG. 24.

Optionally, the input interface 101 may have functions of the receiver in the embodiment in FIG. 26. The logic circuit 102 may have functions of the processor 61 in the embodiment in FIG. 26. The logic circuit 102 may further perform other steps in the decoding methods.

Optionally, the decoding apparatus 100 may further include an output interface. For example, the output interface may output a decoding result.

The decoding apparatus 100 provided in this embodiment of this application may implement the technical solutions shown in the foregoing method embodiments. Implementation principles and beneficial effects thereof are similar to the method embodiments. Details are not described herein again.

An embodiment of this application further provides a storage medium. The storage medium includes a computer program, and the computer program is used to perform the foregoing encoding methods.

An embodiment of this application further provides a storage medium. The storage medium includes a computer program, and the computer program is used to perform the foregoing decoding method.

An embodiment of this application further provides a chip or an integrated circuit, including a memory and a processor.

The memory is configured to store program instructions, and may be further configured to store intermediate data.

The processor is configured to invoke the program instructions stored in the memory, to perform the foregoing encoding methods.

Optionally, the memory may be independent, or may be integrated with the processor. In some implementations, the memory may alternatively be located outside the chip or the integrated circuit.

An embodiment of this application further provides a chip or an integrated circuit, including a memory and a processor.

The memory is configured to store program instructions, and may be further configured to store intermediate data.

The processor is configured to invoke the program instruction stored in the memory, to perform the foregoing decoding methods.

Optionally, the memory may be independent, or may be integrated with the processor. In some implementations, the memory may alternatively be located outside the chip or the integrated circuit.

An embodiment of this application further provides a program product. The program product includes a computer program, the computer program is stored in a storage medium, and the computer program is used to perform the foregoing encoding methods.

An embodiment of this application further provides a program product. The program product includes a computer program, the computer program is stored in a storage medium, and the computer program is used to perform the foregoing decoding methods.

Methods or algorithm steps described with reference to the content disclosed in embodiments of the present invention may be implemented by hardware, or may be implemented by a processor by executing software instructions. The software instructions may include a corresponding software module. The software module may be stored in a random access memory (Random Access Memory, RAM), a flash memory, a read-only memory (Read Only Memory, ROM), an erasable programmable read-only memory (Erasable Programmable ROM, EPROM), an electrically erasable programmable read-only memory (Electrically EPROM, EEPROM), a register, a hard disk, a removable hard disk, a compact disc read-only memory (CD-ROM), or a storage medium of any other form well-known in the art. For example, a storage medium is coupled to a processor, so that the processor can read information from the storage medium and can write information into the storage medium. Certainly, the storage medium may be a component of the processor. The processor and the storage medium may be located in an ASIC. In addition, the ASIC may be located in a base station or a terminal. Certainly, the processor and the storage medium may exist in a receive device as discrete components.

It should be understood that the processor may be a central processing unit (English: Central Processing Unit, CPU for short), or may be another general purpose processor, a digital signal processor (English: Digital Signal Processor, DSP for short), an application-specific integrated circuit (English: Application Specific Integrated Circuit, ASIC for short), or the like. The general-purpose processor may be a microprocessor, or the processor may be any conventional processor or the like. Steps of the methods disclosed with reference to the present invention may be directly executed and accomplished by using a hardware processor, or may be executed and accomplished by using a combination of hardware and software modules in a processor.

The memory may include a high-speed RAM memory; may include a non-volatile memory NVM, for example, at least one magnetic disk memory; or may be a USB flash drive, a removable hard disk, a read-only memory, a magnetic disk, an optical disc, or the like.

The bus may be an industry standard architecture (Industry Standard Architecture, ISA) bus, a peripheral component interconnect (Peripheral Component, PCI) bus, an extended industry standard architecture (Extended Industry Standard Architecture, EISA) bus, or the like. The bus may be classified into an address bus, a data bus, a control bus, or the like. For ease of representation, the bus in the accompanying drawings of this application is not limited to only one bus or only one type of bus.

The storage medium may be implemented by any type of volatile or non-volatile storage device or a combination thereof, for example, a static random access memory (SRAM), an electrically erasable programmable read-only memory (EEPROM), or an erasable programmable read-only memory (EPROM), a programmable read-only memory (PROM), a read-only memory (ROM), a magnetic memory, a flash memory, a disk, or an optical disk. The storage medium may be any available medium accessible by a general-purpose or dedicated computer.

In this application, “at least one” means one or more, and “a plurality of” means two or more. The term “and/or” describes an association relationship for describing associated objects and represents that three relationships may exist. For example, A and/or B may represent the following cases: Only A exists, both A and B exist, and only B exists, where A and B may be singular or plural. In addition, the character “/” in this specification generally indicates an “or” relationship between the associated objects. At least one of the following items (pieces) or a similar expression thereof refers to any combination of these items, including any combination of singular items (pieces) or plural items (pieces). For example, at least one item (piece) of a, b, or c may indicate: a, b, c, a-b, a-c, b-c, or a-b-c, where a, b, and c may be singular or plural.

A person skilled in the art should be aware that, in the foregoing one or more examples, the functions described in embodiments of the present invention may be implemented by using hardware, software, firmware, or any combination thereof. When the functions are implemented by using software, the functions may be stored in a computer-readable medium or transmitted as one or more instructions or code on a computer-readable medium. The computer-readable medium includes a computer storage medium and a communication medium. The communication medium includes any medium that facilitates transmission of a computer program from one place to another. The storage medium may be any available medium accessible by a general-purpose or dedicated computer.

In the several embodiments provided in the present invention, it should be understood that, the disclosed devices and methods may be implemented in other manners. For example, the described device embodiments are merely examples. For example, division into the modules is merely logical function division, or may be other division in actual implementation. For example, a plurality of modules may be combined or integrated into another system, or some features may be ignored or not performed. In addition, the displayed or discussed mutual couplings or direct couplings or communication connections may be implemented through some interfaces. The indirect couplings or communication connections between the apparatuses or modules may be implemented in electrical, mechanical, or other forms.

The modules described as separate parts may or may not be physically separate, and parts displayed as modules may or may not be physical units, and may be located in one position, or may be distributed on a plurality of network units. A part or all of the modules may be selected according to an actual requirement to achieve the objectives of the solutions of embodiments.

In addition, functional modules in embodiments of the present invention may be integrated into one processing unit, or each of the modules may exist alone physically, or two or more modules are integrated into one module. The unit integrated by the modules may be implemented in a form of hardware, or may be implemented in a form of hardware plus a software function unit.

1. An encoding method, comprising:
obtaining K to-be-encoded bits, wherein K is a positive integer;
determining a second generator matrix, wherein
the second generator matrix comprises T sub-blocks,
a position relationship between two adjacent sub-blocks of the T sub-blocks is determined based on a preset position relationship, and
each sub-block of the T sub-blocks comprises a plurality of first generator matrix cores, wherein T is a positive integer; and
polar encoding the K to-be-encoded bits based on the second generator matrix, to obtain encoded bits.

2. The method according to claim 1, wherein an overlapping portion exists in the two adjacent sub-blocks.

3. The method according to claim 1, wherein a first diagonal of the sub-block comprises the plurality of first generator matrix cores of the sub-block.

4. The method according to claim 1, wherein the plurality of first generator matrix cores in the sub-block are distributed in a lower triangular form.

5. The method according to claim 1, wherein
distribution of the plurality of first generator matrix cores in the sub-block is the same as distribution of elements in a second generator matrix core,
a quantity of elements in the second generator matrix core is the same as a quantity of sub-matrices in the sub-block, and
a sub-matrix in the sub-block is a first generator matrix core among the plurality of first generator matrix cores of the sub-block, or a zero matrix.

6. The method according to claim 5, wherein the distribution of elements in the second generator matrix core satisfies B_{N}F₂^{⊗(log}^{₂}^{(N))}.

7. The method according to claim 5, wherein the quantity of sub-matrices in the sub-block is 2*2.

8. The method according to claim 7, wherein
the determining the second generator matrix comprises determining the second generator matrix based on a first generator matrix;
the first generator matrix comprises a first sub-block and a second sub-block, and a first sub-matrix in the first sub-block overlaps a second sub-matrix in the second sub-block; and
coordinates of the first sub-matrix in the first sub-block are (2, 2), and coordinates of the second sub-matrix in the second sub-block are (1, 1).

9. The method according to claim 5, wherein the quantity of sub-matrices in the sub-block is 4*4.

10. The method according to claim 9, wherein
the determining the second generator matrix comprises determining the second generator matrix based on a first generator matrix; and
the first generator matrix comprises a first sub-block and a second sub-block, and four first sub-matrices in the first sub-block overlap four second sub-matrices in the second sub-block, wherein
coordinates of the four first sub-matrices in the first sub-block are (3, 3), (3, 4), (4, 3), and (4, 4); and
coordinates of the four second sub-matrices in the second sub-block are (1, 1), (1, 2), (2, 1), and (2, 2).

11. A decoding method, comprising:
receiving polar encoded bit information; and
polar decoding the bit information based on a second generator matrix, to obtain polar decoded bits, wherein
the second generator matrix comprises T sub-blocks,
a position relationship between two adjacent sub-blocks of the T sub-blocks is determined based on a preset position relationship, and
each sub-block of the T sub-blocks comprises a plurality of first generator matrix cores, wherein T is a positive integer.

12. The method according to claim 11, wherein the bit information comprises N′ first log-likelihood ratio (LLR) sequences, wherein N′ is a positive integer.

13. The method according to claim 12, wherein
the N′ first LLRs comprise T first LLR sequences, and the first LLR sequence comprises at least two first LLRs; and
the polar decoding comprises:
determining T second LLR sequences corresponding to the T first LLR sequences, wherein one of the first LLR sequences corresponds to one or more groups of unencoded bits, and one of the second LLR sequences corresponds to one group of unencoded bits; and
performing polar decoding based on the T second LLR sequences.

14. An encoding apparatus, comprising:
at least one processor; and
one or more memories coupled to the at least one processor and storing programming instructions for execution by the at least one processor, to:
obtain K to-be-encoded bits, wherein K is a positive integer;
determine a second generator matrix, wherein
the second generator matrix comprises T sub-blocks,
a position relationship between two adjacent sub-blocks of the T sub-blocks is determined based on a preset position relationship, and
each sub-block of the T sub-blocks comprises a plurality of first generator matrix cores, wherein T is a positive integer; and
polar encode the K to-be-encoded bits based on the second generator matrix, to obtain encoded bits.

15. The apparatus according to claim 14, wherein an overlapping portion exists in the two adjacent sub-blocks.

16. The apparatus according to claim 14, wherein a first diagonal of the sub-block comprises the plurality of first generator matrix cores of the sub-block.

17. The apparatus according to claim 14, wherein the plurality of first generator matrix cores in the sub-block are distributed in a lower triangular form.

18. The apparatus according to claim 14, wherein
distribution of the plurality of first generator matrix cores in the sub-block is the same as distribution of elements in a second generator matrix core,
a quantity of elements in the second generator matrix core is the same as a quantity of sub-matrices in the sub-block, and
a sub-matrix in the sub-block is a first generator matrix core among the plurality of first generator matrix cores of the sub-block, or a zero matrix.

19. The apparatus according to claim 18, wherein the distribution of elements in the second generator matrix core satisfies B_{N}F₂^{⊗(log}^{₂}^{(N))}.

20. The apparatus according to claim 18, wherein the quantity of sub-matrices in the sub-block is 2*2 or 4*4.
